(19) United States
(12) Patent Application Publication
(10) Pub. No.: US 2019/0138682 A1
(43) Pub. Date: May 9, 2019

(54) ENGINEERING CHANGE ORDER (ECO) CELL ARCHITECTURE AND IMPLEMENTATION

(71) Applicant: QUALCOMM Incorporated, San Diego, CA (US)

(72) Inventors: Anthony Correale, JR., Raleigh, NC (US); William Goodall, III, Cary, NC (US)

(21) Appl. No.: 16/181,456

(22) Filed: Nov. 6, 2018

Related U.S. Application Data
(60) Provisional application No. 62/582,406, filed on Nov. 7, 2017.

(51) Int. Cl. G06F 17/50; G03F 1/70

(52) U.S. Cl. CPC G06F 17/5077; G06F 17/5022; G03F 1/70

(57) ABSTRACT

Engineering change order (ECO) cell architecture and implementation is disclosed. In particular, exemplary aspects disclosed herein provide a generic cell structure that may be readily modified to effect an ECO without requiring extensive mask changes beyond one or two levels including the level in which the cell is located. Further, this generic cell structure can be “parked” fairly deep in the manufacturing process, such as in the middle-end-of-line (MEOL), so that fewer changes to other masks are needed in the event of a change. The generic cell may further act as a filler cell for pattern density. Inclusion of such a generic cell in a circuit design can help alleviate the need for extensive mask redesign and accompanying delays in the production of finished silicon.

### PRIORITY CLAIM

The present application claims priority under 35 U.S.C. § 119(e) to U.S. Provisional Patent Application Ser. No. 62/582,406, filed on Nov. 7, 2017 and entitled “ENGINEERING CHANGE ORDER (ECO) CELL ARCHITECTURE AND IMPLEMENTATION,” the contents of which is incorporated herein by reference in its entirety.

### BACKGROUND

### Field of the Disclosure

The technology of the disclosure relates generally to improving engineering change order (ECO) designs in the manufacture of integrated circuits (ICs).

### II. Background

Computing devices have become increasingly common in modern society. Early computers were the size of a room and employed vacuum tubes to provide rudimentary mathematical calculations. In contrast, modern computing devices provide myriad multimedia, telephony, word processing, and other functions in a relatively small package relying on integrated circuits (ICs). The industry feels market pressure to provide ever increasing processing options in increasingly small products. While ICs have generally obeyed Moore's Law, continued advances in IC functionality in a smaller package is stressing manufacturing capabilities.

Current IC manufacturing processes rely on sequences of masks used in stages to create multi-level ICs such as an active layer that may include one or more transistors with multiple layers of metal positioned thereover to provide interconnections between different transistors and provide connections to exterior pins. Vias or other vertical elements allow interconnections between layers. As the complexity of the IC increases, the mask count to make the IC also increases.

It is common to refer to the size of a channel between a source and a drain of a transistor as a process node size. Early ICs had process node sizes in the micrometer range. Current ICs are in the nanometer range with current designs calling for sub-ten nanometer process node sizes. As the process node size decreases into the low nanometer range, it is common to use a double or multi-pattern mask process for individual lithography steps for fabricating ICs. As an example, for a foundry to place two wires on the lowest metal layer (M0 ) on the tightest pitch with existing deep-ultraviolet lithography, foundries have had to resort to dual-patterning with some offering quad-patterning. That is, two masks are needed to process the dual-patterned M0. The same is true for cut-masks which allow for tighter end-to-end spaces of an existing layer, such as a polysilicon layer (sometimes shortened to poly or poly layer) and a “metal layer”-to-“diffusion layer” layer (sometimes shortened to metal-to-diffusion layer or MD layer or even just MD). The use of such multi-pattern mask processes further increases the number of masks required in the manufacturing process. For example, a typical IC having a seven nanometer (7 nm) process node size with fifteen levels of interconnecting metal may require more than eighty (80) masks.

Layers that are typically multi-patterned are the poly layer, the MD layer, metal layer-to-poly layer (sometimes shortened to MP), the vias between the diffusion layer and MD and/or M0 (sometimes referred to as VD), the vias between the poly or MP layer and M0 (sometimes referred to as VG), the cutting of the MD layer (sometimes referred to as CMD), the cutting of the poly layer (sometimes referred to as CPO), the cutting of the M0 layer (sometimes referred to as cut-M0 ), M0, the via between MP or MD to M0 (sometimes referred to as V0), M1, M2, M3, and the V1 vias. As used herein, the word “via” includes its use as an acronym for “vertical interconnect access.” Each of these multi-patterned layers adds masks and complexity to the manufacturing process.

Because most of the multi-patterned layers are used early in the manufacturing process, most of the complexity in the manufacturing process is associated with the front-end-of-line (FEOL) transistor formation and middle-end-of-line (MEOL or MOL) local interconnect and lower levels of metal formation. Back-end-of-line (BEOL) handling of metals and vias is considered to begin around the fourth level of metal (sometimes referred to as M4 (or M3 if the first level of metal is M0 )).

While definitions of what is properly considered MEOL may vary, the M1), CMD MP, VD, VG, M0 -M3, and CM0 layers and the V0, V1, and V2 vias can be considered to be fabricated as MEOL fabrication steps. In a typical mask process, each “mask” may actually be a sequence of masks. For example, if the MD mask sequence is the thirtieth (30th) “mask,” it should be appreciated that there may be two masks associated with a dual-patterned MD. In an eighty (80) mask sequence process, FEOL and MEOL may constitute approximately the first forty (40) sequences of masks for example. By way of further example, the MD may be around the thirtieth sequence of masks in the fabrication sequence.

It should be appreciated that such complex, multi-mask processes are expensive. For example, when designs are released to a foundry or other manufacturing, it is common for the mask set cost to exceed one million dollars. Additionally, the manufacturing time is on the order of three months for the first silicon to be ready. Consequently, if a design defect is detected, there is a substantial expense in redesigning the masks and a substantial delay in resuming manufacturing.

Very Large Scale Integration (VLSI) designs that are used in IC fabrication characteristically employ filler cells in regions of “white” space (i.e., regions without active circuitry) to afford pattern density for process uniformity. These filler cells generally have no function other than to maintain pattern uniformity, although in some cases, the filler cells are defined as decoupling capacitors and may be made using many, if not all, of the manufacturing masks. Others of these filler cells are defined with the goal of potentially being utilized to correct a logic error. That is, the function of the cell is predefined as an inverter, AND, Negative AND (NAND), OR, negative OR (NOR), or the like. When a logic error is found, one or more filler cells may potentially be used to address the logic error. However, the viability of such use is dependent on the composition and location of the filler cell(s) relative to the logic error.

To avoid complete redesigns of the masks used when there is a design detect, many designers try to use a filler cell in a manner referred to as an engineering change order (ECO) and may integrate ECO capability into designs. Then, if a design defect is detected, the changes can be made beginning at the level incorporating the ECO instead of starting from the beginning with all FEOL, MEOL, and many of the BEOL masks being regenerated with accompanying expense and delay. However, while such filler cells may be configured to create needed simple logic functions, the filler cells may still need many FEOL masks to be redefined. Accordingly, there remains a need for a better solution to handling design defects.

### SUMMARY OF THE DISCLOSURE

Aspects disclosed in the detailed description include engineering change order (ECO) cell architecture and implementation. In particular, exemplary aspects disclosed herein provide a generic cell structure with a first level of transistors formed on appropriate diffusion regions that may be readily modified to effect an ECO without requiring extensive mask changes beyond one or two levels including the level in which the cell is located. Further, this generic cell structure can be “parked” fairly deep in the manufacturing process, such as in the middle-end-of-line (MEOL), so that fewer changes to other masks are needed in the event of a change. The generic cell may further act as a filler cell for pattern density. Inclusion of such a generic cell in a circuit design can help alleviate the need for extensive mask redesign and accompanying delays in the production of finished silicon.

In exemplary aspects, a generic cell is formed that can be used as a generic filler cell or a decoupling capacitor (DCAP) cell. However, the generic cell can also be customized as needed by “locking” the front-end-of-line (FEOL) masks and including power rails on the first or lowest metal layer (sometimes referred to as M0 ) that extend entirely across the cell so as to he able to couple to adjacent cells. Each of the respective common standard cell power rails (VDD and VSS) is coupled to another adjacent M0 layer previously allocated for signal routing within the standard cell and now forms the ECO generic cell's dedicated power or ground source. Each of the power rails may be coupled to a split internal polysilicon rail which in turn is coupled to another layer through a jumper to provide power more conveniently to interior elements. The generic cell also includes a cut shape isolating connectivity between a first M1 track and a third M1 track. Vias are used to carry power from the other layer to elements in the cell. By selective placement of other vias, the generic cell may be customized. However, the vias do not disrupt any of the FEOL masks and generally have minimal or no impact on higher level masks. The net effect of the flexibility of the generic cell disclosed herein is to facilitate easy and simple repurposing of the generic cell to fix logic errors and the like. The ease of such repurposing reduces costs of mask redesigns and expedites establishing a revised mask set thereby reducing time delays incurred during redesigns.

In this regard in one aspect, an ECO cell is disclosed. The ECO cell includes a rectilinear outline comprising four edges. The ECO cell also includes a circuit. The circuit includes a first metal layer (M0 ) comprising a first portion and a second portion. The first portion is positioned generally adjacent a first edge of the four edges and is configured to be coupled to a power source. The second portion is positioned generally adjacent a second edge of the four edges and is configured to be coupled to a ground. The first edge and the second edge are opposite one another on the rectilinear outline. The first metal layer further includes a first M0 track, a second M0 track, a third M0 track, a fourth M0 track, and a fifth: M0 track. The circuit also includes a second metal layer (M1) including a first M1 track, a second M1 track, and a third M1 track. The circuit also includes a first path coupling the first portion of the first metal layer to the first M0 track through a first VG via, a first jumper, and a first VD via. The first VG via is positioned proximate an intersection of the first edge and a third edge and the first VD via. The circuit also includes a second path coupling the second portion of the first metal layer to the fifth M0 track through a second VG via, a second jumper, and a second VD via. The second VG via is positioned proximate an intersection of the second edge and the third edge. The circuit includes a first V0 via coupling the first M1 track to the third M0 track. The circuit also includes a second V0 via coupling the third M1 track to the third M0 track. The circuit also includes a third V0 via coupling the second M1 track to the second M0 track. The circuit also includes a fourth V0 via coupling the second M1 track to the fourth M0 track.

In another aspect, a DCAP cell is disclosed. The DCAP cell includes a first generic cell including a first circuit. The first circuit includes a first metal layer M0 ) including a first portion and a second portion. The first portion is positioned generally adjacent a first edge of four edges and is configured to be coupled to a power source. The second portion is positioned generally adjacent a second edge of the four edges and is configured to be coupled to a ground. The first edge and the second edge are opposite one another on a rectilinear outline. The first metal layer further includes a first M0 track, a second M0 track, a third M0 track, a fourth M0 track, and a fifth M0 track. The first circuit also includes a second metal layer (M1) including a first M1 track, a second M1 track, and a third M1 track. The first circuit also includes a first path coupling the first portion of the first metal layer to the first M0 track through a first VG via, a first jumper, and a first VD via. The first VG via is positioned proximate an intersection of the first edge and a third edge and the first VD via. The first circuit also includes a second path coupling the second portion of the first metal layer to the fifth M0 track through a second VG via, a second jumper, and a second VD via. The second VG via is positioned proximate an intersection of the second edge and the third edge. The first circuit also includes a first V0 via coupling the first M1 track to the third M0 track. The first circuit also includes a second V0 via coupling the third M1 track to the third M0 track. The first circuit also includes a third V0 via coupling the second M1 track to the second M0 track. The first circuit also includes a fourth V0 via coupling the second M1 track to the fourth M0 track. The DCAP cell also includes a second generic cell adjacent to the first generic cell. The second generic cell includes a second circuit.

In another aspect, a tie-high circuit is disclosed. The tie-high circuit includes a first generic cell including a first circuit. The first circuit includes a first metal layer (M0 ) including a first portion and a second portion. The first portion is positioned generally adjacent a first edge of four edges and is configured to be coupled to a power source. The second portion is positioned generally adjacent a second edge of the four edges and is configured to be coupled to a ground. The first edge and the second edge are opposite one another on a rectilinear outline. The first metal layer further includes a first M0 track, a second. M0 track, a third M0 track, a fourth M0 track, and a fifth M0 track. The first circuit also includes a second metal layer (M1) including a first M1 track, a second M1 track, and a third M1 track. The first circuit also includes a first path coupling the first portion of the first metal layer to the first M0 track through a first VG via, a first jumper, and a first VD via. The first VG via is positioned proximate an intersection of the first edge and a third edge and the first VD via. The first circuit also includes a second path coupling the second portion of the first metal layer to the fifth M0 track through a second VG via, a second jumper, and a second VD via. The second VG via is positioned proximate an intersection of the second edge and the third edge. The first circuit also includes a first V0 via coupling the first M1 track to the third M0 track. The first circuit also includes a second V0 via coupling the third M1 track to the third M0 track. The first circuit also includes a third V0 via coupling the second M1 track to the second M0 track. The first circuit also includes a fourth V0 via coupling the second M1 track to the fourth M0 track. The tie-high circuit also includes a second generic cell adjacent to the first generic cell. The second generic cell includes a second circuit. The first and fifth M0 tracks are continuous across the first generic cell and the second generic cell.

In another aspect, a tie-low circuit is disclosed. The tie-low circuit includes a first generic cell including a first circuit. The first circuit includes a first metal layer (M0) including a first portion and a second portion. The first portion is positioned generally adjacent a first edge of four edges and is configured to be coupled to a power source. The second portion is positioned generally adjacent a second edge of the four edges and is configured to be coupled to a ground. The first edge and the second edge are opposite one another on a rectilinear outline. The first metal layer further includes a first M0 track, a second M0 track, a third M0 track, a fourth M0 track, and a fifth M0 track. The first circuit also includes a second metal layer (M1) including a first M1 track, a second M1 track, and a third M1 track. The first circuit also includes a first path coupling the first portion of the first metal layer to the first M0 track through a first VG via, a first jumper, and a first VD via. The first VG via is positioned proximate an intersection of the first edge and a third edge and the first VD via. The first circuit also includes a second path coupling the second portion of the first metal layer to the fifth M0 track through a second VG via, a second jumper, and a second VD via. The second VG via is positioned proximate an intersection of the second edge and the third edge. The first circuit also includes a first V0 via coupling the first M1 track to the third M0 track. The first circuit also includes a second V0 via coupling the third M1 track to the third M0 track The first circuit also includes a third V0 via coupling the second M1 track to the second M0 track. The first circuit also includes a fourth V0 via coupling the second M1 track to the fourth M0 track. The tie-low circuit also includes a second generic cell adjacent to the first generic cell. The second generic cell includes a second circuit. The first and fifth M0 tracks are continuous across the first generic cell and the second generic cell.

In another aspect, a method of manufacturing an integrated circuit (IC) is disclosed. The method includes designing a circuit with one or more ECO cells as filler cells. The method also includes making a mask stack to be used in the manufacture of the IC. The method also includes identifying a design error in the IC. The method also includes identifying at least one of the one or more ECO cells that may be modified to address the design error. The method also includes modifying a design of the IC to modify the at least one of the one or more ECO cells. The method also includes modifying the mask stack deep in an MEOL process. The method also includes making the IC based on the modified mask stack.

### BRIEF DESCRIPTION OF THE FIGURES

FIG. 1 is a top plan view of a conventional logic cell used in an integrated circuit (IC);

FIG. 2A is a top plan view of an unconfigured engineering change order (ECO) logic cell according to an exemplary aspect of the present disclosure;

FIGS. 2B-2F are exploded views of selected layers of the ECO logic cell of FIG. 2A;

FIG. 3 is a top plan view of the logic cell of FIG. 2A configured to be a one-finger inverter circuit;

FIG. 4 is a top plan view of the ECO logic cell of FIG. 2A configured to be a two-finger inverter circuit;

FIG. 5 is a top plan view of the ECO logic cell of FIG. 2A configured to be a NAND circuit;

FIG. 6 is a top plan view of the ECO logic cell of FIG. 2A configured to be a NOR circuit;

FIG. 7A is a top plan view of the ECO logic cell of FIG. 2A configured to be a stacked inverter circuit;

FIG. 7B is a schematic circuit diagram of the stacked inverter circuit of FIG. 7A;

FIG. 8A is a top plan view of two ECO logic cells from FIG. 2A configured to be a tie-high circuit;

FIG. 813 is a schematic circuit diagram of the tie-high circuit of FIG. 8A;

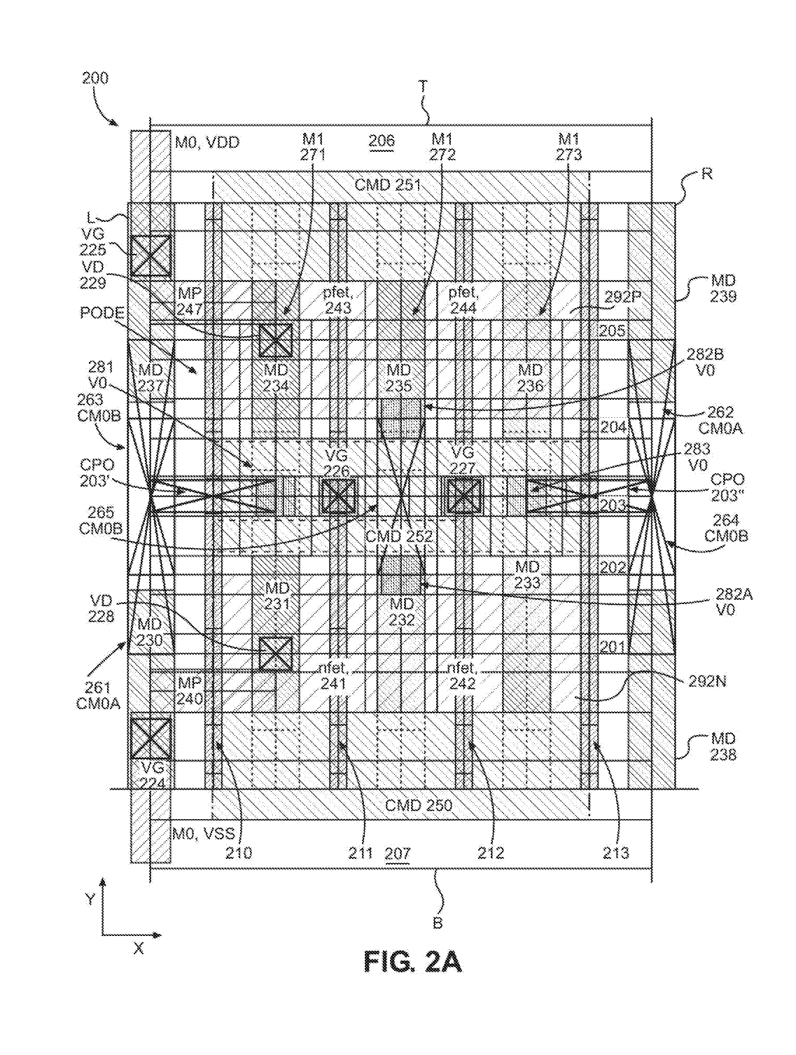

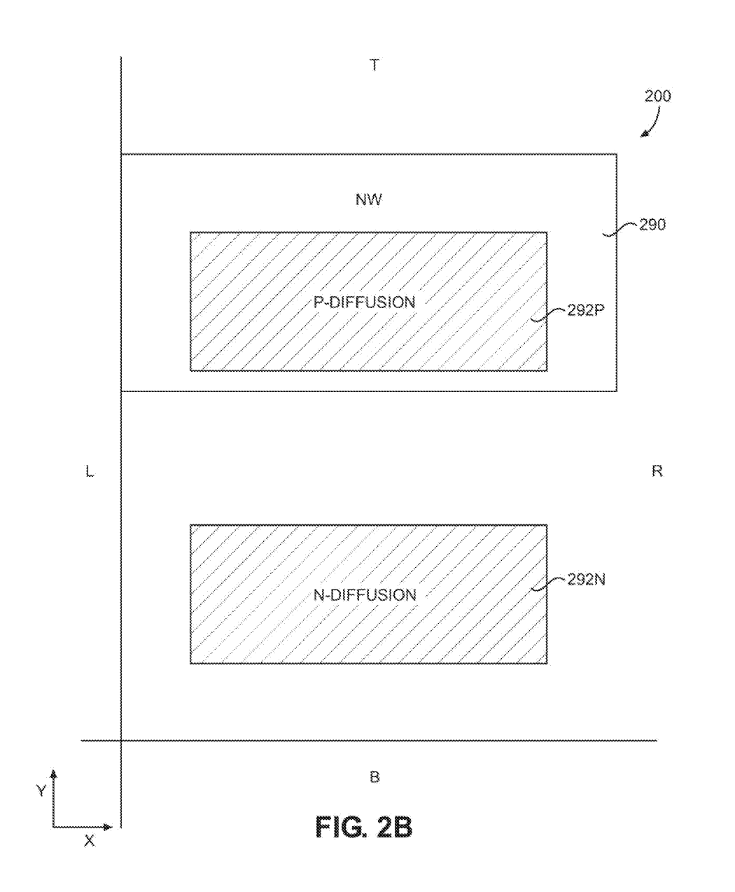

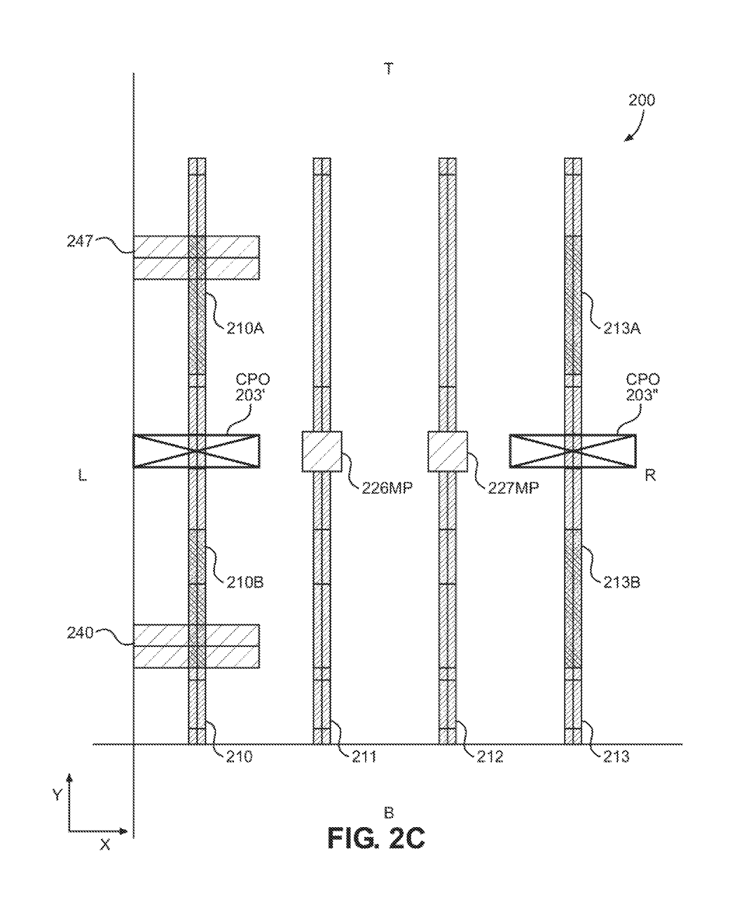

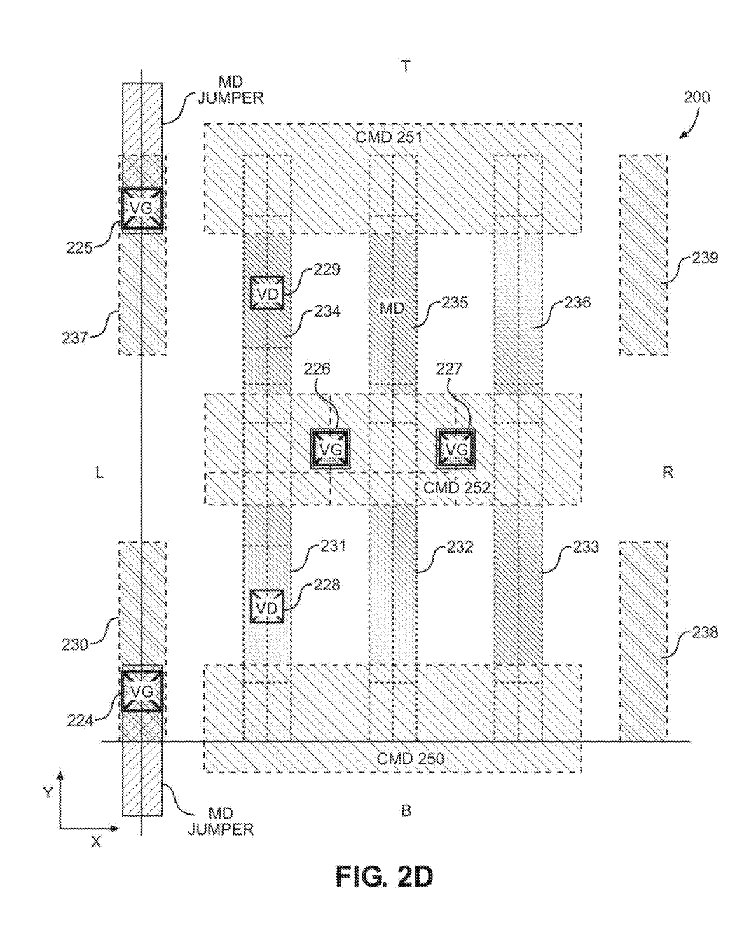

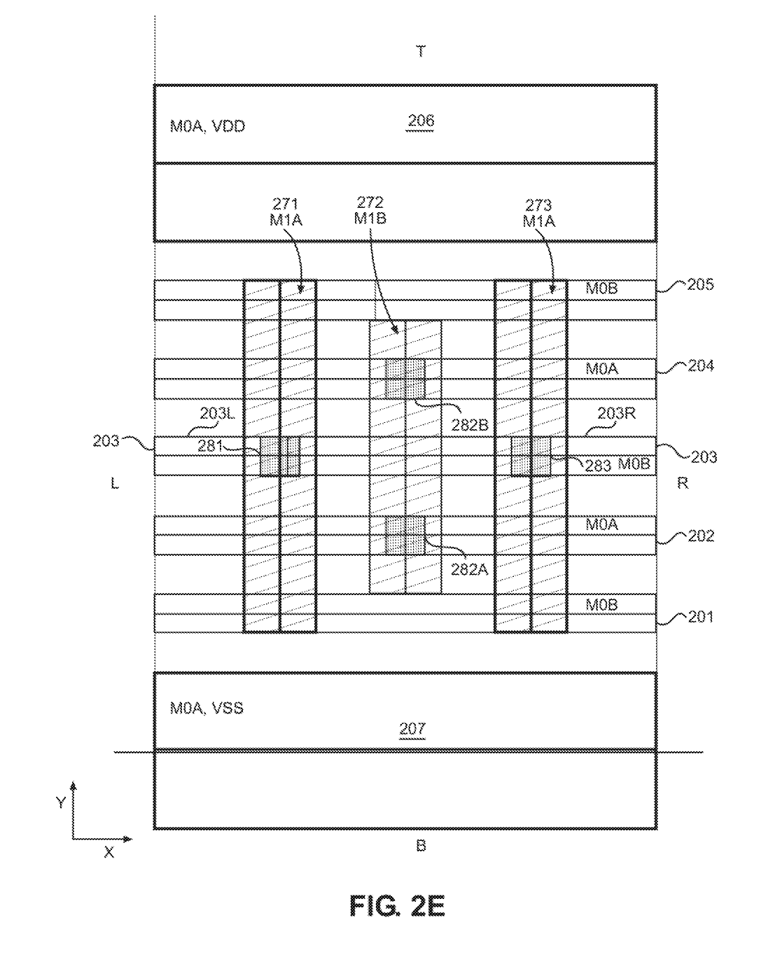

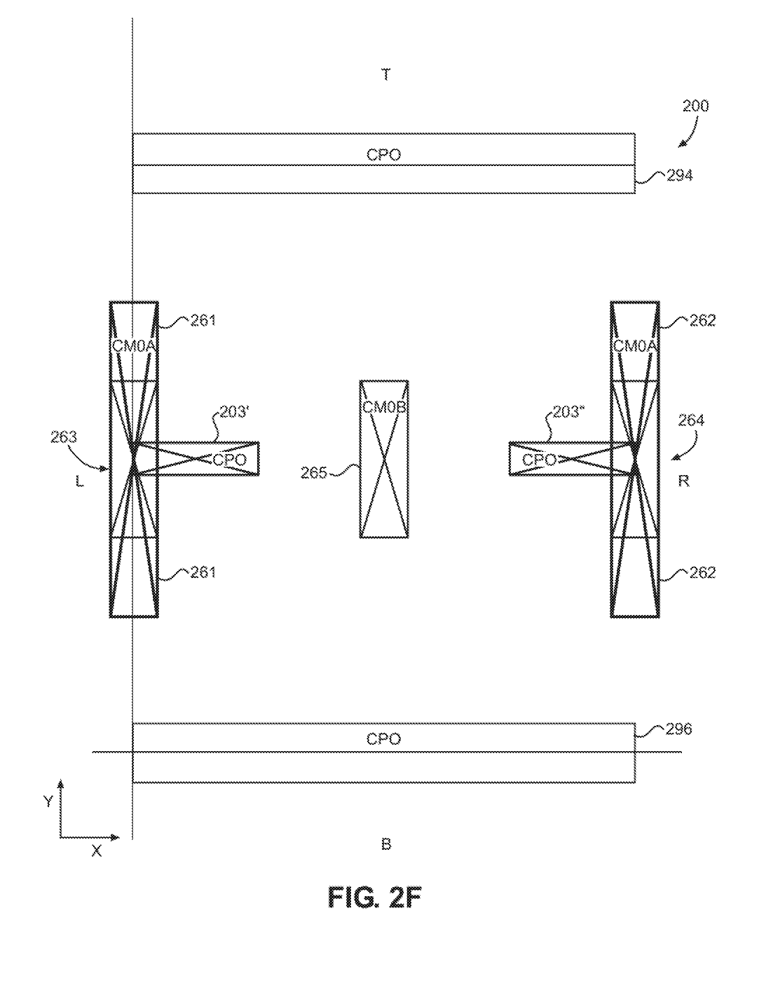

FIG. 9A is a top plan view of two ECO logic cells from FIG. 2A configured to be a tie-low circuit;

FIG. 9B is a schematic circuit diagram of the tie-low circuit of FIG. 9A;

FIG. 10A is a top plan view of two ECO logic cells from FIG. 2A configured to be a decoupling capacitor (DCAP) circuit;

FIG. 10B is a schematic circuit diagram of the DCAP circuit of FIG. 10A;

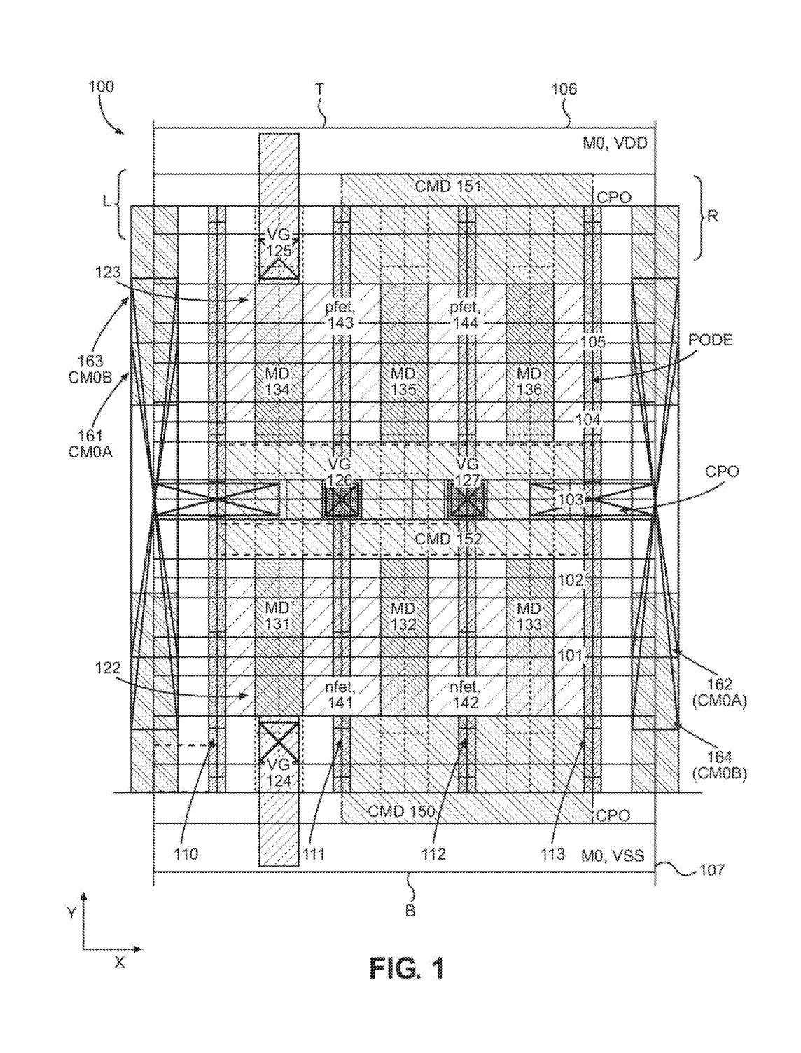

FIG. 11 is a top plan view of a different conventional standard logic cell having a taller height than the logic cell of FIG. 1 and that accommodates fin Field-Effect Transistors (FETs) (finFETs) having more fins than finFETs in FIG. 1;

FIG. 12A is a top plan view of a second unconfigured ECO logic cell according to an exemplary aspect of the present disclosure;

FIGS. 12B-12F are exploded views of select layers of the ECO logic cell of FIG. 12A

FIG. 13 is a top plan view of the ECO logic cell of FIG. 12A configured to be a one-finger inverter circuit;

FIG. 14 is a top plan view of the ECO logic cell of FIG. 12A configured to be a two-finger inverter circuit;

FIG. 15 is a top plan view of the ECO logic cell of FIG. 12A configured to be a NAND circuit;

FIG. 16 is a top plan view of the ECO logic cell of FIG. 12A configured to be a NOR circuit;

FIG. 17 is a top plan view of the ECO logic cell of FIG. 12A configured to be a stacked inverter circuit;

FIG. 18A is a top plan view of two ECO logic cells from FIG. 12A configured to be a tie-high circuit;

FIG. 18B is a schematic circuit diagram of the tie-high circuit of FIG. 18A;

FIG. 19A is a top plan of two ECO logic cells from FIG. 12A configured to be a tie-low circuit;

FIG. 19B is a schematic circuit diagram of the tie-low circuit of FIG. 19A;

FIG. 20A is a top plan view of two ECO logic cells from FIG. 12A configured to be a DCAP circuit;

FIG. 20B is a schematic circuit diagram of the DCAP circuit of FIG. 20A;

FIG. 21 is a flowchart illustrating an exemplary process for customizing the ECO logic cell of FIG. 2A or FIG. 12A; and

FIG. 22 is a block diagram of an exemplary processor-based system that can include the ECO logic cell of FIG. 2A or FIG. 12A,

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects,

Aspects disclosed in the detailed description include engineering change order (ECO) cell architecture and implementation. In particular, exemplary aspects disclosed herein provide a generic cell structure that may be readily modified to effect an ECO without requiring extensive mask changes beyond one or two levels including the level in which the cell is located. Further, this generic cell structure can be “parked” fairly deep in the manufacturing process, such as in the middle-end-of-line (MEOL), so that fewer changes to other masks are needed in the event of a change. The generic cell may further act as a filler cell for pattern density. Inclusion of such a generic cell in a circuit design can help alleviate the need for extensive mask redesign and accompanying delays in the production of finished silicon.

In exemplary aspects, a generic cell is formed that can be used as a filler cell, but also be customized as needed by “locking” the front-end-of-line (FEOL) masks and including power rails on the first or lowest metal layer (sometimes referred to as M0) that extend entirely across the cell so as to be able to couple to adjacent cells. Each of the respective common standard cell power rails (VDD and VSS) is coupled to another adjacent M0 layer previously allocated for signal routing within the standard cell and now forms the ECO generic cell's dedicated power or ground source. Each of the power rails may be coupled to a split internal polysilicon rail which in turn is coupled to another layer through a jumper to provide power more conveniently to interior elements.

Vias are used to carry power from the other layer to elements in the cell. By selective placement of other vias, the generic cell may be customized. However, the vias do not disrupt any of the FEOL masks and generally have minimal or no impact on higher level masks. The net effect of the flexibility of the generic cell disclosed herein is to facilitate easy and simple repurposing of the generic cell to fix logic errors and the like. The ease of such repurposing reduces costs of mask redesigns and expedites establishing a revised mask set thereby reducing time delays incurred during redesigns.

Before addressing exemplary aspects of the present disclosure a few definitions are provided to assist with acronyms that may appear elsewhere in the disclosure.

MEOL is introduced above and may sometimes be referred to as MOL. MEOL or MOL is generally associated with local interconnect and lower levels of metal formation.

FEOL is associated with transistor formation and occurs first in the manufacturing process.

Back-end-of-line (BEOL) is generally associated with handling metals layers and vias. It should be appreciated that the precise lines between FEOL/MEOL/BEOL are imprecise, but as a general rule, BEOL begins around the fourth metal layer with FEOL and MEOL occurring before this fourth metal layer is formed.

Metal layers exist to allow interconnections between active elements. While the precise number of metal layers may vary, there are typically more than four, and perhaps more than fifteen metal layers. These are referred to as M0-Mx where x is an integer one less than the number of metal layers. Thus, if there are eight metal layers, these would be denoted M0-M7. M0 refers to the lowest metal layer—i.e., closest to the layer with the active elements thereon and M7 would be the highest metal layer (generally the last metal layer created in the circuit). Some within the industry refer to the lowest metal layer as M1 and count upwards therefrom such that the highest metal layer has a number equal to the actual number of metal layers. The present disclosure does not use this alternative naming convention and refers to the lowest metal layer as M0.

In addition to the naming conventions associated with metal layers, many of the other layers in an integrated circuit (IC) are also named. A non-exclusive list follows, with the understanding that within the industry, other variations on these names may exist.

In this regard, polysilicon layers (sometimes shortened to poly or poly layers) are usually used to form gates for transistors and in some processes are actually metal but still referred to as poly.

An MD layer is a “metal layer”-to-“diffusion layer” layer, e.g., the layer in between the metal layer M0 and the diffusion layer.

An MP layer is a metal layer-to-poly layer.

A VD layer includes the vias between the diffusion layer and MD and/or M0 layers.

A VG layer includes the vias between the poly or MP layer and M0 layer.

A CMD layer is the layer that performs the cutting of the MD layer.

A CPO layer is the layer that performs the cutting of the poly layer.

A Cut-M0 layer or CM0 is the layer that performs the cutting of the M0 layer.

A V0 layer includes the vias between the MP or MD layers to the M0 layer.

To better assist in understanding exemplary aspects of the present disclosure, and particularly to highlight flexibility present in the ECO cells of the present disclosure, an explanation of a conventional logic cell 100 is provided with reference to FIG. 1. With the understanding of the conventional logic cell 100, exemplary aspects of the present disclosure are discussed below beginning at FIG. 2, and it should be appreciated that the contrast between the conventional logic cell 100 and exemplary aspects of the present disclosure will be more readily apparent.

In this regard, FIG. 1 illustrates the conventional logic cell 100. The conventional logic cell 100 is rectilinearly shaped and is four (4) poly pitches wide from left edge (L) to right edge (R). In an exemplary aspect, the logic cell 100 is three hundred nanometers (300 nm) from a top (T) to a bottom (B). While illustrated as a four poly pitch wide cell, it should be appreciated that other widths that are integer multiples of poly pitches may be used to implement other various logic functions as needed or desired.

The logic cell 100 includes five (5) signal wires, M0 tracks 101-105, running on an M0 mask layer in a lateral direction (i.e., L or R (or R to L)). The top (T) of the logic cell 100 has an edge with a shared power line (VDD), M0 track 106, running laterally across the logic cell 100 on the M0 layer. The bottom (B) of the logic cell 100 has an edge with a shared ground (VSS), M0 track 107, running laterally across the logic cell 100 on the M0 layer. The logic cell 100 has polysilicon shapes 110-113 running orthogonal to the M0 tracks (i.e., from T to B (or B to T)). Polysilicon shapes 111 and 112 are associated with n-type Field-Effect Transistors (FETs) (NFETs) 141 and 142 and p-type FETs (PFETs) 143 and 144 formed by the intersection of diffusion shapes 122 and 123 with the polysilicon shapes 111 and 112. The polysilicon shape 110 is proximate edge L and a left edge of the diffusion shapes 122 and 123 while polysilicon shape 113 is proximate edge R and a right edge of the diffusion shapes 122 and 123. As illustrated, the polysilicon shapes 110 and 113 do not form any devices. Polysilicon shapes 110 and 113 are sometimes referred to as poly-on-diffusion-edge (PODE) and are inset one-half a poly-to-poly and diffusion-to-diffusion ground rule space from the left edge L and the right edge R of the logic cell 100 to ensure no connectivity between adjacently-related cells.

With continued reference to FIG. 1, MD shapes 131-136 provide overlays to the diffusion shapes 122 and 123 to reduce diffusion resistance while allowing connection to the M0 tracks (i.e., 101-107). VD vias provide a means to connect the MD layer to the M0 layer (none shown). Sometimes VG vias, which are normally used to connect a polysilicon gate to the M0 layer through an MP layer, can be used to make M0 connections to the MD layer. Thus, as illustrated, VG vias 124 and 125 are used to connect the MD shape 131 and MD shape 134 to the M0 track 107 and the M0 track 106, respectively. In this manner, VSS and VDD are coupled to the MD shape 131 and MD shape 134, respectively. VG vias 126 and 127 overlay MP shapes thereby making connections to polysilicon gates of the FETs 141, 143 and 142, 144, respectively, and connections to M0 track 103.

With continued reference to FIG. 1, the logic cell 100 further includes CMD shapes 150 and 151, which are located along the bottom and the top of the logic cell 100, respectively. The CMD shapes 150 and 151 are cuts that ensure no MD connections between adjoining cells to the top or the bottom of the logic cell 100. CMD shape 152, located in the ‘center,’ is a cut that isolates the MD shapes 131-133 from the MD shapes 134-136. Further, the CMD shape 152 also isolates MP shapes located on the polysilicon shapes 111 and 112. The center CMD shape 152 must be applied over the MP shapes connecting to the polysilicon gates to ensure no shorting between MD and MP layers. Depending on the logic function being realized by the logic cell 100, the center CMD shape 152 may be customized.

Since there are no direct MD connections between the source/drains (created by the diffusion shape 122) of the NFETs 141 and 142 and the source/drains (created by the diffusion shape 123) of the PFETs 143 and 144, all connections to the metal layers are made on the M1 layer running vertically in parallel to the polysilicon shapes 111 and 112. While not shown in FIG. 1, these M1 shapes will provide connections between the M0 and M1 layers through V0 vias. Connections between the MD and M0 layers will be made with VD/VG vias, as was shown for the power and ground connections.

Like the CMD shapes which were used to cut the MD layer to ensure no connectivity along the top and the bottom and within the logic cell 100 as needed, cut poly (CPO) shapes perform a similar function with respect to elements in the poly layer. A cut-M0 (CM0) set of shapes is employed along the cell left/right boundaries to ensure no lateral connectivity between cells on the M0 layer. These shapes, like many others, can be multi-patterned to afford the best lithography. The M0 shapes are one such set that are multi-patterned. In FIG. 1, the M0 shapes associated with the M0 tracks 101, 103, and 105 belong to one pattern set while the M0 shapes associated with the M0 tracks 102, 104. 106, and 107 belong to another pattern set. Since the M0 layer is dual-patterned, it stands to reason that the CM0 shapes are dual-patterned as well. In FIG. 1, the left and right edges of the logic cell 100 have CM0 patterns CM0A 161 and 162 and CM0 patterns CM0B 163 and 164 to ensure no left/right connectivity on the M0 layer between cells to the left or right. Like the use of CMD shapes within the cell ‘center,’ CM0A and CM0B shapes can do the same for the respective M0 shapes.

MD shapes 130, 137, 138, and 139 are on the border of the logic cell 100 and are shared across the boundary of laterally-placed cells. MD shapes 130, 137, 138, and 139 are used for pattern matching such that there is no gap in the MD utilization across cell boundaries.

It should be appreciated that terms like top, left, right, and bottom are used for convenience and are relative to the orientation of the Figure, and not strictly required for implementation.

Multi-patterning (dual or otherwise) is used to afford the best lithography for a given lithography light source (e.g., deep ultraviolet or the like). M0, CM0, MD, CMD, MP, poly, CPO, VD, VG, V0, V1, CM1, and M1 may be dual-patterned. M2, V1, M3, and V2 are likewise likely dual-patterned. As can be seen, the use of multi-patterning while affording improved lithography and thus density, comes at an increased manufacturing cost and complexity as the mask count increases dramatically (i.e., by a factor of two for each dual-patterned layer). Also, what may be noted, is that for each mask, there is a sequence of application with the last level of metal being near the last in the sequence and the FEOL at the beginning of the sequence. The MEOL masks are in the middle of the sequence. The diffusion, poly, CPO, implants, MD, CMD, M0, and CM0 are some of the early FEOL and MEOL masks. Accordingly, it is less than ideal to change any of these masks for an ECO because changes at these low levels usually involve additional changes to higher layers as adjustments are made and also involve the need for more overall mask changes. The VD and VG masks are near the middle of the mask sequence, and toward the middlelend of the MEOL. The V0, M1, and following masks are all later in the sequence.

Given the expense and time delays involved in changing mask sets during circuit design, designers would appreciate a flexible ECO cell that can be repurposed with minimal impact on the mask set and, if there is no need to repurpose the ECO cell, act as a filler cell or an ECO cell purposed as a decoupling cap (DCAP). Exemplary aspects of the present disclosure mimic the logic cell 100 by preserving the masks in the FEOL and most of the MEOL while allowing configurations that repurpose the ECO cell using VD and limited masks beyond the VD mask sequence to afford distinct logic functions for use in ECOs.

Against the backdrop of conventional logic cell 100, it is desirable to provide a cell architecture that can plug-and-play with other cells employed in an IC, act as a filler cell for pattern density, and be programmable with minimum mask changes deep in the MEOL to implement a design ECO. An overview of a cell that satisfies these desires may be summarized as follows.

Specifically, the cell may have a four poly track uniform configuration (two poly gates per cell) with the ability to configure complex functions of higher drive strength circuits by using multiple instances of a background ECO cell placed either laterally or vertically. The cell should have a common poly pitch relative to standard cells within the IC and fixed threshold implants. The cell may include finFETs having a fin count consistent with the cell height. The cell should have a common power and ground rail relative to standard cells within the IC. The power and ground connections may be to ancillary signal wire or wires dedicated to supporting power and ground to retargetable ECO cells without altering the existing distribution of surrounding cells. The cell may have fixed power contacts on the respective power rails. The cell may have fixed power contacts on any ancillary signal tracks on a background cell and may further have the ability to add additional contacts during customization. The cell may have fixed VG and MP connections to the poly gates. There may be fixed MP usage. There may be fixed M1 connections to each gate and output thereby reducing the need for any M1 mask changes. The cell may include fixed V0 vias within the cell to make fixed connections to predefined locations in the M1 layer. The cell may allow the customization to be done exclusively on the VD layer for many logic functions, minimizing the impact of changes on any other layer. Other logic functions may be instantiated through the use of two or more ECO cells with VD customization along with M2 and V1 interconnections between ECO cells or the use of M1 and/or V1 and M2 for ECO cells placed vertically with respect to one another. Such capability allows for modifications on only two masks along with any V1 and M2 changes for laterally-connected cells and M1, V1, and potentially M2 for vertically-connected cells. Still further, the cell may require no optical proximity correction or additional pattern fills for the FEOL or most of the MEOL, as only the VD mask is changed for customization.

In this regard, FIG. 2A illustrates an exemplary cell structure that is well suited to meeting the criteria set forth above. Understanding that FIG. 2A is particularly visually busy, FIGS. 2B-2F illustrate selected layers in isolation for better understanding of FIG. 2A. ECO cell 200 is similar to the logic cell 100 of FIG. 1 in terms of height (e.g., 300 nm in the y-axis direction (B to T or T to B)) and arrangement of poly, M0, and CPO layers. It should be appreciated that device size is dictated early in the FEOL process, and thus the ECO cell 200 will use a fixed diffusion and FEOL mask set consistent with the rest of the IC. While the term “cell” is used, it should be appreciated that a cell is a repeatable circuit that fits within a defined space. Thus, a cell is a group of transistor and interconnect structures that provides a function such as a Boolean logic function or a storage function. Thus, the ECO cell 200 has a rectilinear shape with parallel exterior opposite edges.

As illustrated, the ECO cell 200 has an N-well 290 (illustrated in FIG. 2B) in which a p-type diffusion region 292P is formed. The ECO cell 200 further has an n-type diffusion region 292N (see FIG. 2B for these elements in isolation). The N-well and diffusion regions are the lowest level and are formed in or on the lowest substrate level generally. The diffusion regions 292P and 292N are wide enough in the x-axis direction (L to R or R to L) to support four poly pitches (e.g., polysilicon shapes 210-213, better illustrated in FIG. 2C). Again, it should be appreciated that other widths that are integer multiples of poly pitches may be used. However, for consistency, ECO cell 200 is four poly pitches wide. The size of the diffusion regions 292N and 292P support three (3) fins for all devices.

FIG. 2C illustrates the four polysilicon shapes 210-213. Polysilicon shapes 210 and 213 are sometimes referred to as poly-on-diffusion-edge (PODE) and are inset one-half a poly-to-poly and diffusion-to-diffusion ground rule space from the left edge L and the right edge R of the ECO cell 200 to ensure no connectivity between adjacently-related cells. MP shapes 240 and 247 are sometimes referred to as jumpers, because MP shapes 240 and 247 provide connections from MD shapes 230 and 237 to MD shapes 231 and 234, respectively. The MP shapes 240 and 247 also connect to the left edge polysilicon shape 210 at the PODE boundary. Also illustrated in FIG. 2C are MP shapes 226MP and 227MP, which reflect that the MP layer is present to provide electrical connections for VG vias 226 and 227, respectively to polysilicon shapes 211 and 212, respectively. CPO rectangular shapes 203′ and 203″ are also illustrated on top of polysilicon shapes 210 and 213, respectively thereby splitting each of the respective polysilicon shapes into two separate pieces. Regions 210A, 210B, 213A, and 213B on the polysilicon shapes 210 and 213 reflect where the polysilicon shapes 210 and 213 meet the diffusion edge or PODE. Polysilicon shapes 211 and 212 lie interiorly of the diffusion edge.

FIG. 21) illustrates the MD, CMD, VG, and VD layers. In particular, the MD layer includes MD shapes 230-239 formed in part by cut shapes CMD 250-252. VD vias 228 and 229 are coupled to the MD shapes 231 and 234, respectively. Similarly VG vias 224-227 provide connections as better explained below. MD jumpers allow two cells that share a common MD with a common set of VG vias (e.g., VG vias 224 and 225). If the two cells align such that their power and ground VG contacts are vertically aligned to one another, then a post-processing algorithm can allow them to share a larger centrally-located via in the center of the power rail if desired.

FIG. 2E illustrates the M0, V0 and M1 layers. In particular, M0 tracks 206 and 207 form VDD and VSS rails, respectively. M0 tracks 201, 202, 204, and 205 extend across the ECO cell 200 in the x-axis direction (L to R or R to L). M0 track 203 is actually cut by CM0B 265 (see FIGS. 2A, 2F) thereby converting M0 track 203 into two electrically-isolated M0 metal shapes 203L and 203R. V0 vias 281, 282A, 282B, and 283 couple the M0 layer to the M1 layer. The M1 layer includes M1 shapes 271-273 extending in the y-axis direction (B to T or T to B). As a note of nomenclature, the A-B designations (other than for vias 282A and 282B) in FIG. 2E reflect multi-masks. That is, using two masks, M0A elements are made with one mask, and M0B elements are made with a second mask. Similarly, using two masks, M1A elements are made with one mask, and M1B elements are made with a second mask.

FIG. 2F illustrates the CPO layer and the CM0 layer. In particular, the CPO layer includes CPO shapes 294 and 296, which cut the polysilicon layer to make sure that there is not a polysilicon connection with vertically adjacent cells. The CPO layer also includes CPO shapes 203′ and 203″. CPO shape 203′ cuts polysilicon shape 210 at the mid-point of the ECO cell 200, and no connection is made between VDD and VSS. CPO shape 203″ cuts polysilicon shape 213 on the right most edge ensuring no unwanted connections. CM0 shapes 261 and 263 may cut the M0 metal layer on the left edge to prevent lateral connections. Similarly, CM0 shapes 262 and 264 may cut the M0 metal layer on the right edge to prevent lateral connections. The CM0 shapes 261 and 262 are CM0A mask shapes and CM0 shapes 263 and 264 are CM0B shapes. These A and 13 designations are for separate cuts within a dual mask process for the same layer to achieve the desired shape.

With that explanation of the specific shapes of the various layers, when they are put together into the ECO cell 200 as illustrated in FIG. 2A, a generic ECO cell is provided. Some differences between the logic cell 100 and the ECO cell 200 are highlighted to show the versatility of the ECO cell 200.

VG vias 226 and 227 are in the same positions as the VG vias 126 and 127 of FIG. 1. Note that since there are no other VD customizations, the placement of the VG vias 126 and 127 have no specific function, but are left in place to show that the ECO cell 200 may be created with minimal changes to the conventional logic cell 100 to allow plug and play functionality.

With continued reference to FIG. 2A, one of the differences between the logic cell 100 and the ECO cell 200 is the placement of the VG vias associated with making connections to the M0 VSS and M0 VDD rails. Specifically, VG vias 224 and 225 are now located on the MD shapes 230 and 237, respectively. That is, instead of being placed interiorly of the first rail (the polysilicon shape 110), but before the second rail (the polysilicon shape 111), as illustrated in FIG. 1, the VG vias 224 and 225 are positioned outside the first rail (polysilicon shape 210), closer to the edge L. Thus, the contacts are now on the cell left-edge L. Thus, the VSS and VDD M0 rails now connect to the MD shapes 230 and 237, respectively. Ramifications of this placement will be further explored below.

With continued reference to FIG. 2A, the ECO cell 200 has M0 tracks 201 and 205, which are dedicated to VSS and VDD, respectively in addition to the M0 VSS rail proximate the bottom of the ECO cell 200 and the M0 VDD rail proximate the top of the ECO cell 200. Connections to the M0 tracks 201 and 205 are through fixed VD vias 228 and 229 respectively. Thus, the path formed from the VG contacts, the jumpers 240 and 247, and the vias 228 and 229 establish the M0 tracks 201 and 205 as the ECO cell 200 VSS and VDD, respectively. When the ECO cell 200 is customized, such customization may use these M0 tracks for VSS and VDD connections rather than have to couple to the M0 tracks 206 and 207 on the top and bottom of the ECO cell 200. The source of NFET 241 and the drain of PFET 243 are connected to VSS and VDD, respectively through the VD vias 228 and 229. The drain of the NFET 241, the source of the NFET 242, and the drain of the NFET 242 remain unconnected in the ECO cell 200 allowing customization as explained in greater detail below. Likewise, the source of the PFET 243, the drain of the PFET 244, and the source of the PFET remain unconnected in the ECO cell 200, again allowing customization as explained in greater detail below.

With continued reference to FIG. 2A, another difference between the logic cell 100 and the ECO cell 200 is the CMD shapes 250 and 251 along the top and bottom edges of the cell. The CMD shapes cut all MD shapes 231-236. Thus, no CMD modifications will be needed during an ECO. The CMD shape 252 is identical to the CMD shape 152 in FIG. 1.

The left and right edge base CM0A shapes 261 and 262 are identical to the CM0A shapes 161 and 162 of the logic cell 100. However, the ECO cell 200 has modified CM0B shapes 263 and 264 only cutting the M0 track 203. Thus, the ECO cell M0 VSS 201 and M0 VDD 205 will be shared across all adjacent ECO cells creating a parallel VSS/VDD path throughout all ECO cells. CM0B 265 is introduced to cut the M0 track 203 at mid-track. This cut breaks the continuity between the device set of NFET 241 and. PFET 243 and the device set of NFET 242 and. PFET 244 through the VG vias 226 and 227, respectively. This CM0B 265 allows the gates of these respective device sets to be connected as needed through other higher sequence masking steps.

The ECO cell 200 incorporates fixed location M1 and V0 via shapes. A first M1 track 271 is located to the left of the VG via 226 in a first M1 track location. A V0 via 281 is located at the intersection of the first M1 track 271 and the M0 track 203. This arrangement forms an M0 to M1 to VG connection. The gates of the first device set of the NFET 241 and the PFET 243 are now connected to the first M1 track 271. Likewise a third M1 track 273 is located to the right of the VG via 227 in a third M1 track location. A V0 via 283 is located at the intersection of the third. M1 track 273 and the M0 track 203. This arrangement forms an M0 to M1 to VG connection. Thus, the gates of the second device set of the NFET 242 and the PFET 244 are now connected to the third M1 track 273. Finally, a second M1 track 272 is located between the first and the third M1 tracks 271 and 273. The second M1 track 272 has two V0 vias associated with it. One V0 via 282A intersects M0 track 202 and another V0 via 282B intersects M0 track 204. Thus, the second M1 track 272 connects the M0 tracks 202 and 204.

With this basic architecture in the ECO cell 200, myriad possibilities are now available to customize the ECO cell 200 in such a manner as to help cure design defects without having to redesign FEOL or early MEOL masks with associated changes throughout the rest of the mask set. As noted before, ECO cells such as the ECO cell 200 may be used singly or in clusters to fill locations throughout an IC.

In one exemplary aspect, the ECO cell 200 may be modified to insert VD vias at the intersections of the second M1 track 272 and the M0 tracks 201 and 204, as well as the intersection of the third M1 track 273 and the M0 tracks 201 and 204. This configuration will tie all NFET diffusions to VSS and all PFET diffusions to VDD. Since all like type diffusions are common, the gates associated with these devices can float. Thus, no M1 connections are made to higher-level metal, which means that no higher-level masks need to be modified.

It should be appreciated that while the M0 and M1 layers are specifically contemplated as providing the functions recited above, it may be possible to move such functions to different metal layers. However, moving off the M0 and M1 layers may impact the ability to leave other masks unchanged as the cell is customized.

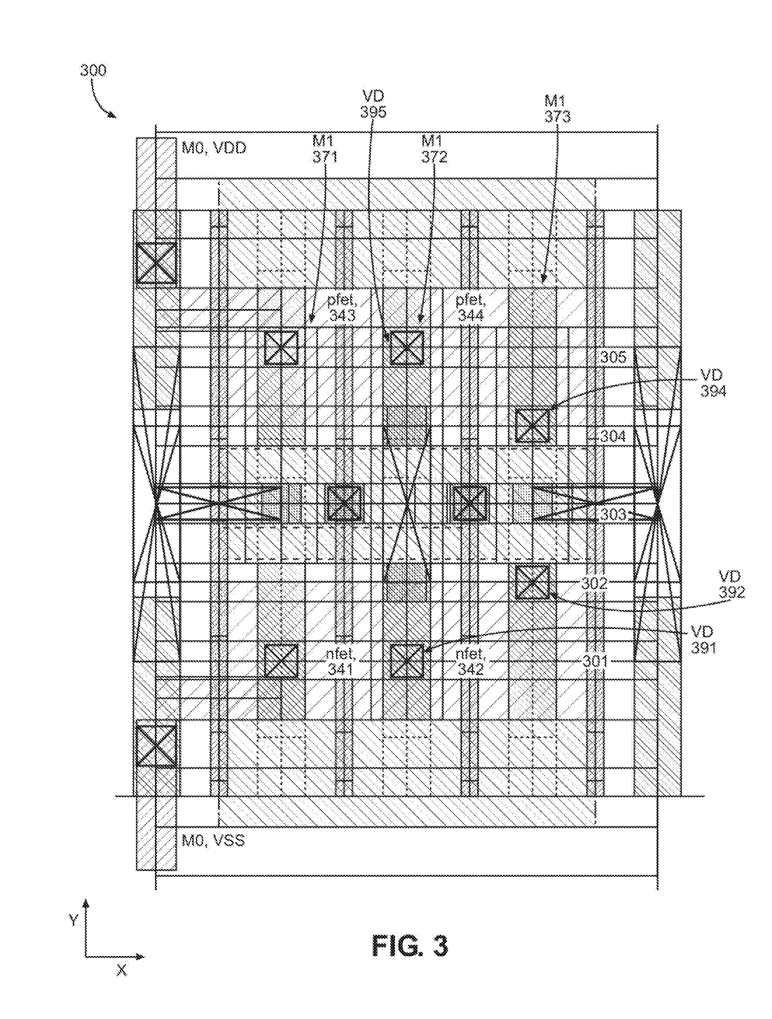

FIGS. 3-10 show possible customizations of the ECO cell 200 of FIG. 2A to provide various different logic functions. Given that the ECO cell 200 has a fixed four (4) poly pitch, any function which needs more than four poly will need multiple ECO cells 200. However, the ECO cell 200 is pre-configured to allow ready coupling to adjacent ECO cells 200 both horizontally and vertically, and such arrangements are specifically contemplated as being within the scope of the present disclosure.

FIG. 3 illustrates the customization of the ECO cell 200 of FIG. 2A to create a single-finger inverter function. In particular, the ECO cell 200 has been modified to an inverter cell 300 by placement of VD vias. That is, to create the single-finger inverter, the source and drain of a first NFET 341 and a first PFET 343 are connected to VSS and VDD, respectively while floating the gate input. These connections are accomplished by adding VD via 391 at the intersection of M1 track 372 and M0 track 301 and VD via 395 at the intersection of the M1 track 372 and M0 track 305. A second device set now has its PFET 344 drain connected to VDD through the VD via 395 and its NFET 342 source connected to VSS through the VD via 391. The source of the PFET is connected to M0 track 304 through VD via 394 and the drain of NFET 342 is connected to M0 track 302 through VD via 392. Since the ECO cell 200 already has V0 vias connecting the M1 track 372 to the M0 tracks 302 and 304, this constitutes the output of the inverter M0 track 303 is unchanged. Thus, the M1 track 372 is the inverter output, and M1 track 373 is the inverter input. M1 track 371 floats. This customization is accomplished through the simple addition of the VD vias 391, 392, 394, and 395. In effect, a change to a single mask effectuates this change from the ECO cell 200 to the inverter cell 300.

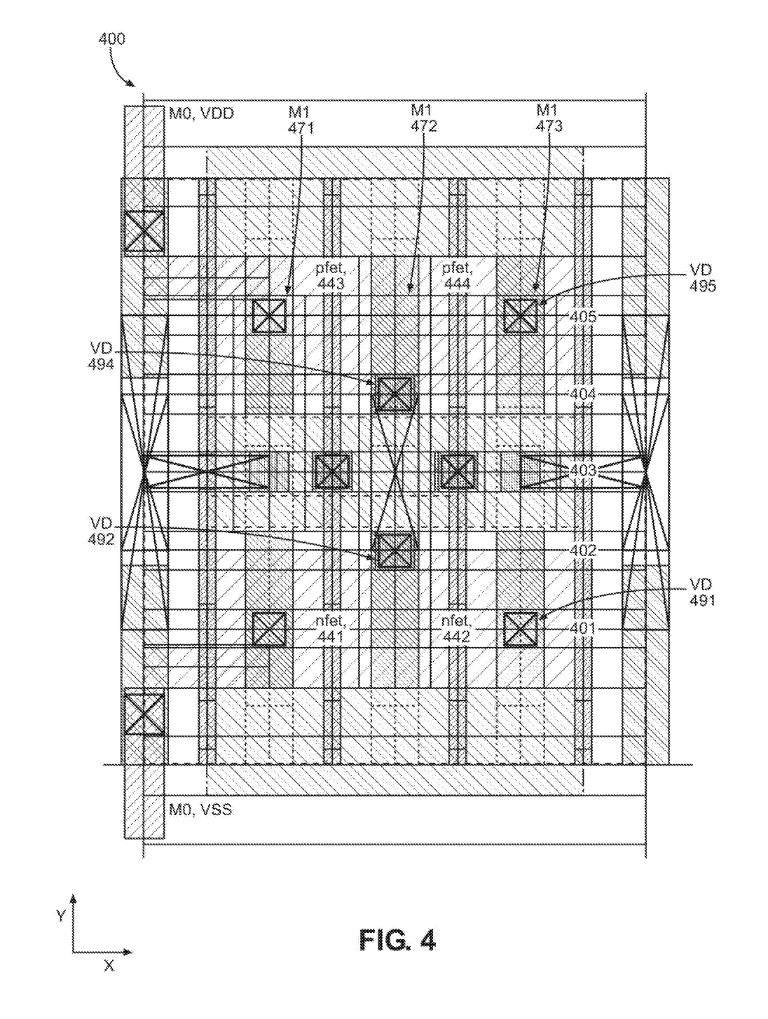

FIG. 4 illustrates the customization of the ECO cell 200 of FIG. 2A to create a two-finger inverter function. Compared to the ECO cell 200, the only difference in inverter cell 400 is the placement of the VD vias. To create a two-finger inverter, the source of a second NFET 442 is connected to VSS by VD via 491 and the drain of a second PFET 444 is connected to VDD by VD via 495. The sources of PFETs 443 and 444 are connected to M0 track 404 through VD via 494. The drain of NFETs 441 and 442 are connected to M0 track 402 through VD via 492. Since the ECO cell 200 already has V0 vias connecting M1 track 472 and M0 tracks 402 and 404, this arrangement constitutes the output of the inverter. M0 tracks 401, 403, and 405 are unchanged. Thus, the M1 track 472 is the inverter output and M1 track 471 and M1 track 473 are the inverter inputs. An M2 strap and associated V1 vias (not shown) will complete connection of the two M1 input tracks when this function is needed. Thus, the only changes to the ECO cell 200 are the addition of the VD vias 491, 492, 494, and 495. To incorporate the inverter cell 400, changes are made to the VD masks, the V1 masks, and the M2 masks.

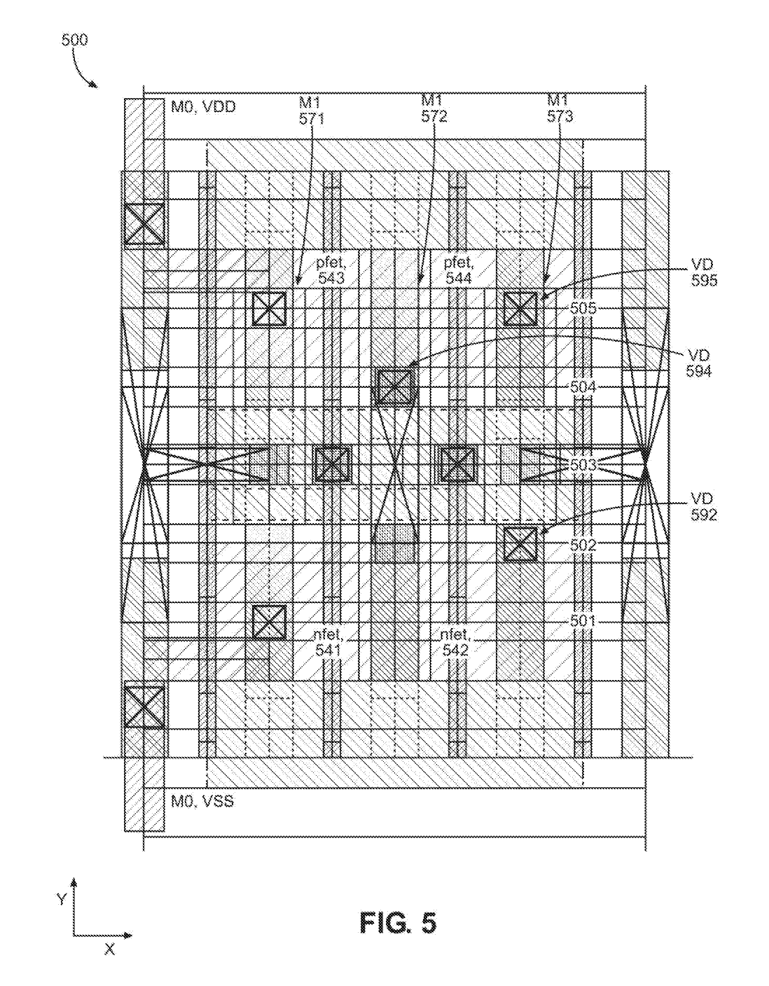

FIG. 5 illustrates the customization of the ECO cell 200 of FIG. 2A into a two-input NAND (NAND2) logic cell 500. Again, the placement of the VD vias controls the customization and is the only change needed. The NAND2 function has A and B input PFETs 543 and 544 in parallel with the output and. VDD while A and B input NFETs 541 and 542 are in series with one another between the output and VSS. Thus, to create the NAND2 logic cell 500, the drain of the PFET 544 is connected to VDD (M0 track 505) using VD via 595, and the sources of both the PFETs 543 and 544 are connected to M0 track 504 by VD via 594. The drain of the series connected NFET 542 is connected to M0 track 502 by VD via 592. M0 tracks 501 and 503 are unchanged. Since the ECO cell 200 already has V0 vias connecting M1 track 572 to M0 tracks 502 and 504, the output of the NAND2 logic cell 500 is available. That is, the M1 track 572 is the NAND2 logic cell 500 output, and M1 track 571 and M1 track 573 are the NAND2 A and B inputs. Again, the only change is the addition of the VD vias 592, 594, and 595, requiring only a change in the VD mask.

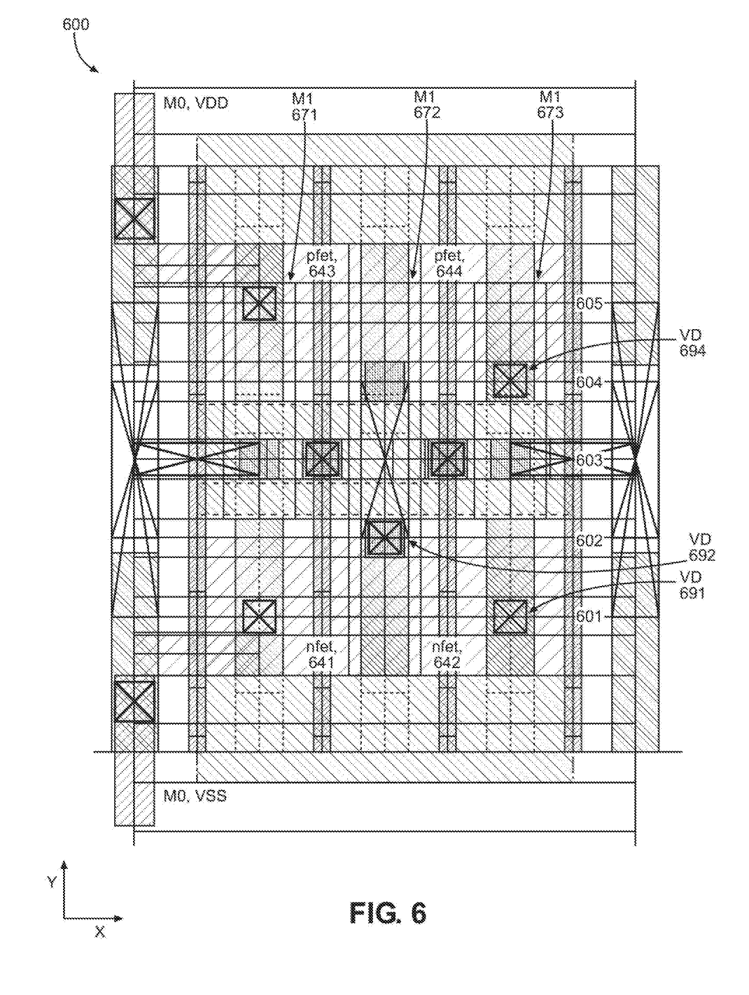

FIG. 6 illustrates the customization of the ECO cell 200 of FIG. 2A into a two-input NOR (NOR2) logic cell 600. Again, the placement of the VD vias controls the customization and is the only change needed. The NOR2 function has A and B input PFETs 643 and 644 in series with one another between VDD and output M0 track 604. A and B input NFETs 641 and 642 are in parallel with one another with their respective sources connected to VSS and shared drains connected to output M0 track 602. Thus, to create the NOR2 logic cell 600, the drain of the PFET 644 is connected to the output M0 track 604 using VD via 694, and the sources of both the NFETs 641 and 642 are connected to the output M0 track 602 using VD via 692. The drain of the parallel connected NFET 642 is connected to VSS M0 track 601 with VD via 691. Since the ECO cell 200 already has V0 vias connecting M1 track 672 to M0 tracks 602 and 604, the output is present. That is, the M1 track 672 is the NOR2 logic cell 600 output, and M1 track 671 and M1 track 673 are the NOR2 logic cell 600 A and B inputs. M0 tracks 603 and 605 are unchanged. Again, the only changes to the ECO cell 200 are the inclusion of the VD vias 691, 692, and 694.

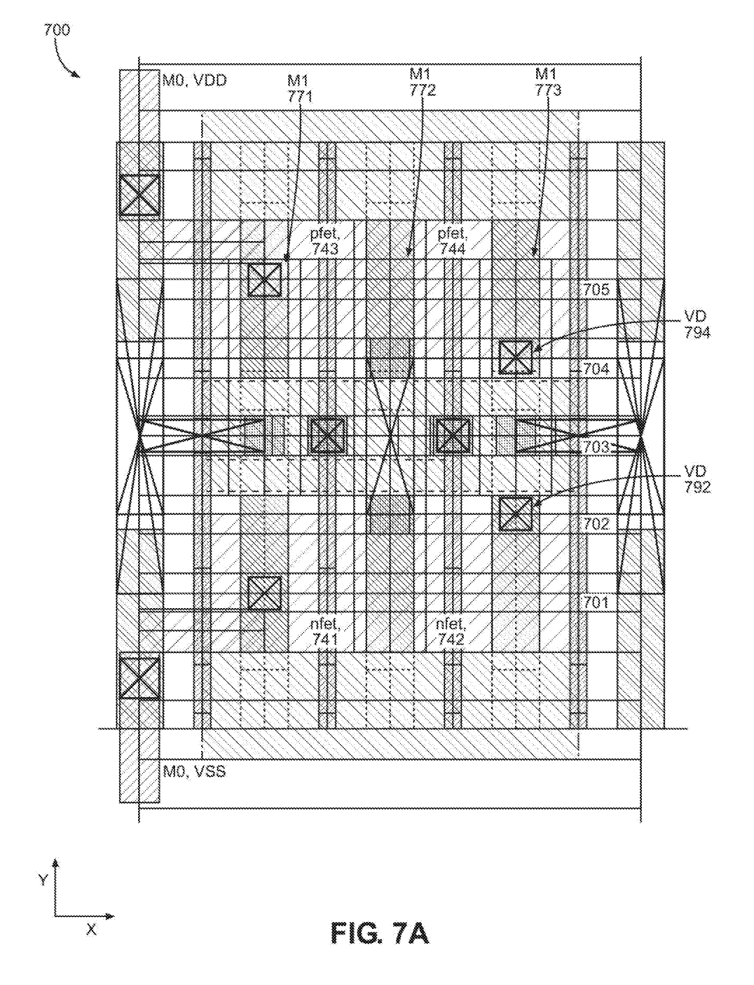

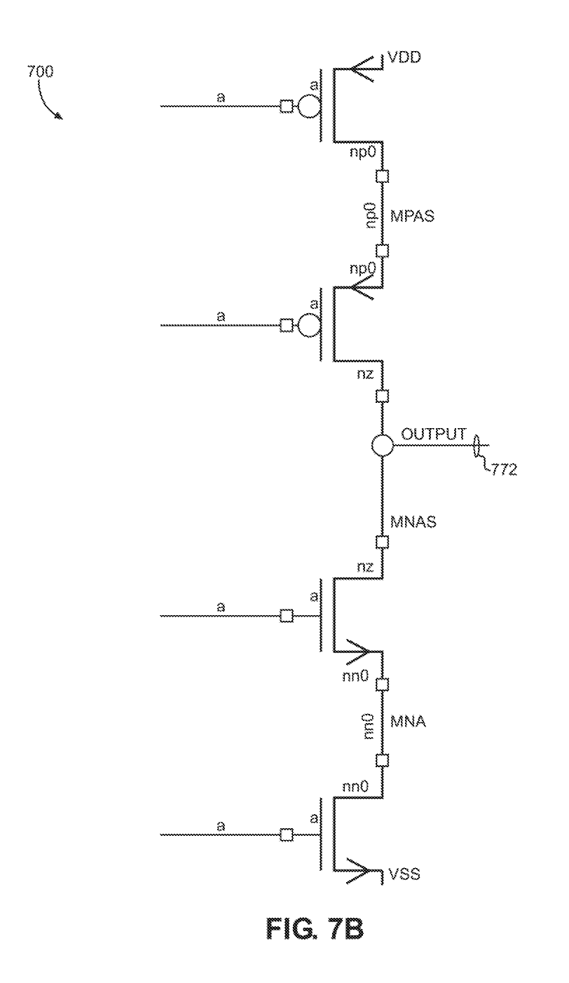

FIG. 7A illustrates the customization of the ECO cell 200 of FIG. 2A to create a single-finger stacked inverter cell 700. FIG. 7B is a schematic view of the stacked inverter cell 700. In particular, the stacked inverter cell 700 is formed from a series stack of two PFETs 743 and 744 connected between VDD and the output and a series stack of two NFETs 741 and 742 connected between the output and VSS. The gates of all the devices are common. The ECO cell 200 is modified by the addition of VD vias. In particular, the drain of a second NFET 742 is connected to M0 output track 702 by means of VD via 792, and the drain of a second PFET 744 is connected to M0 track 704 by VD via 794. Since the V0 vias of the ECO cell 200 already connect M1 track 772 to the M0 tracks 702 and 704, the output is already formed. That is, the M1 track 772 is the stacked inverter output and M1 track 771 and M1 track 773 are the gate inputs. The gate inputs will be connected together using a higher-level metal and an associated V1 via. Thus, changes to the VD masks and the higher-level metal masks are required but are still not considered too disruptive to the entire mask stack. The change to the ECO cell 200 is the addition of the VD vias 792 and 794. M0 tracks 701, 703, and 705 are unchanged.

In some technologies, there is a restriction on connecting gates of FETs directly to a power supply or ground. Thus, there may be a need for circuits that support a logic tie-up/tie-high and/or a logic tie-down/tie-low. The ECO cell 200 of FIG. 2A is readily modified to support such structures.

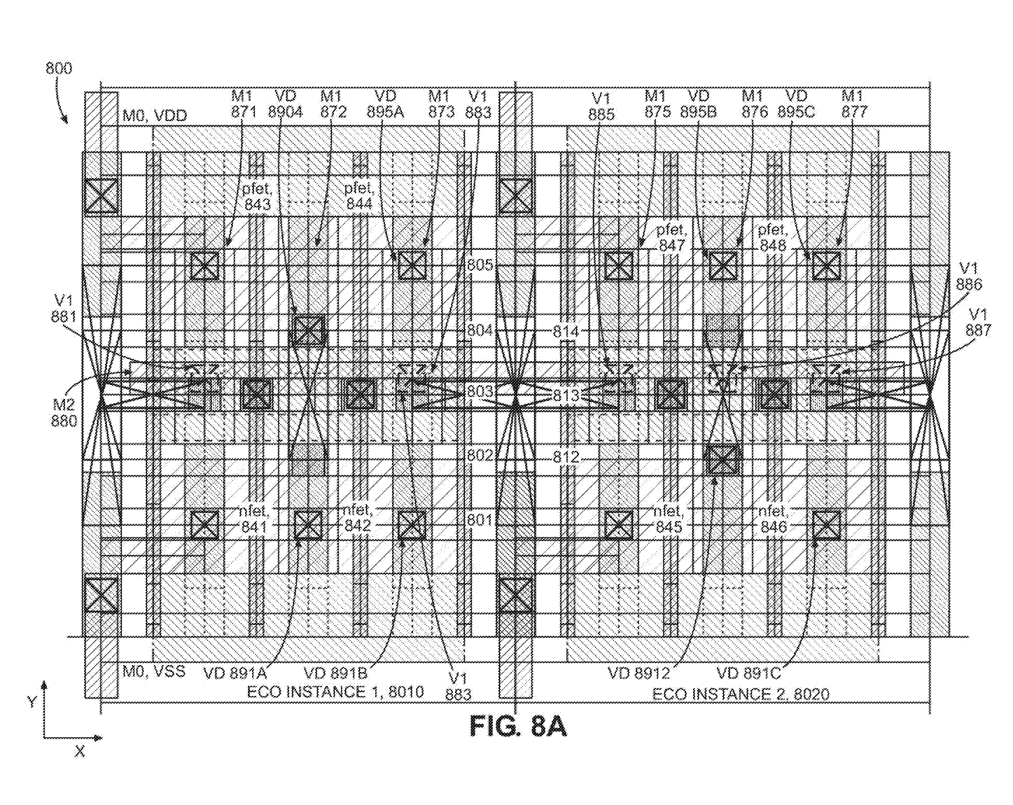

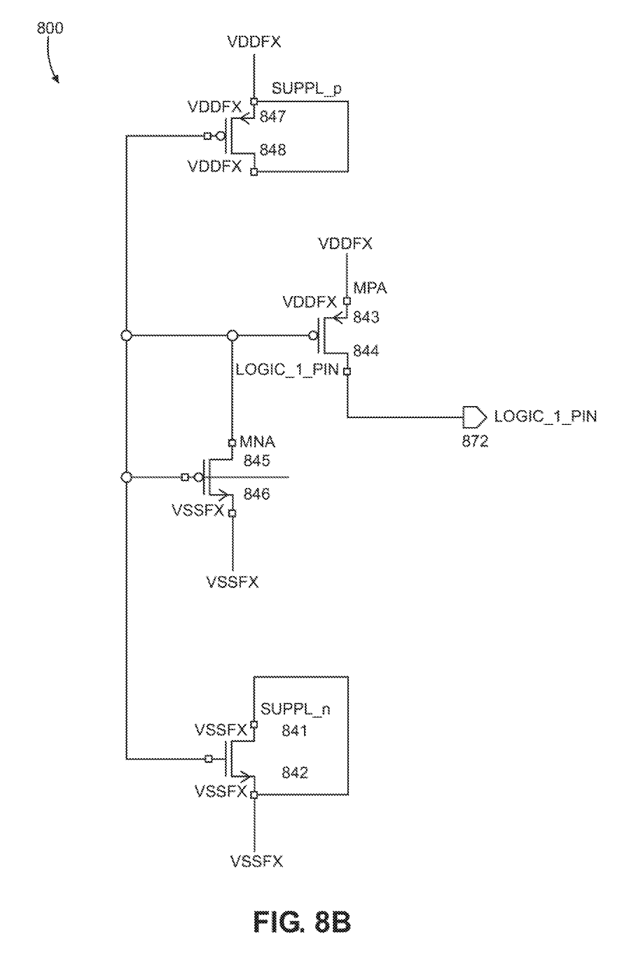

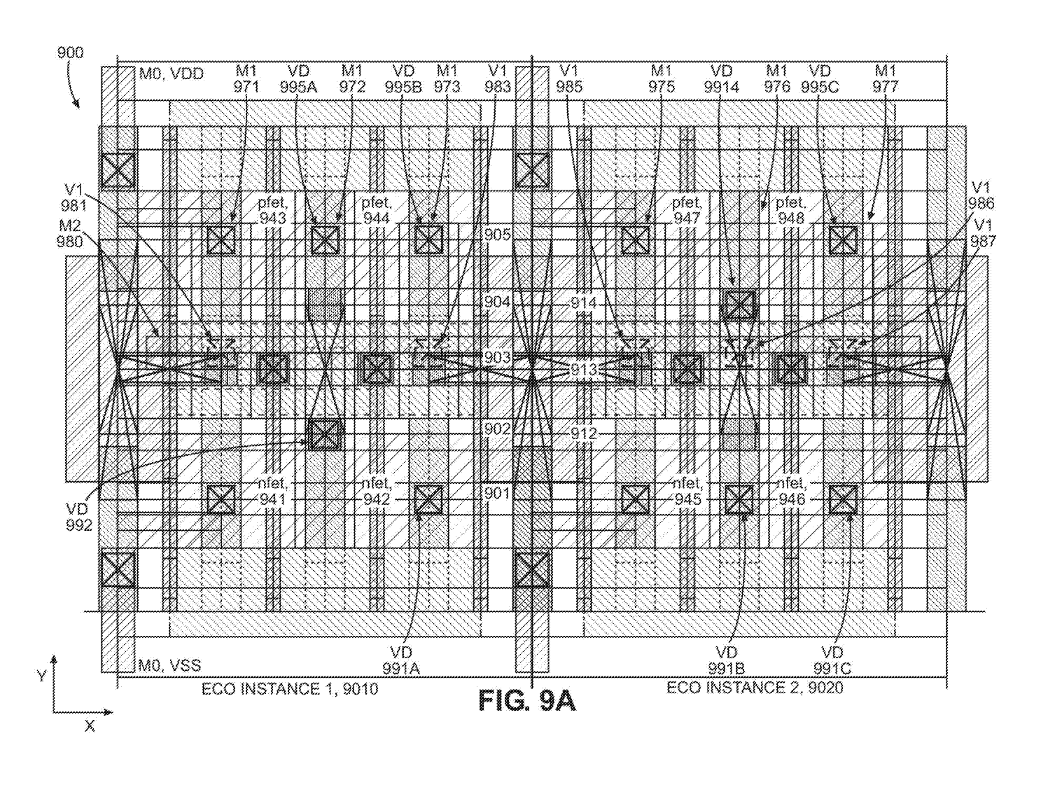

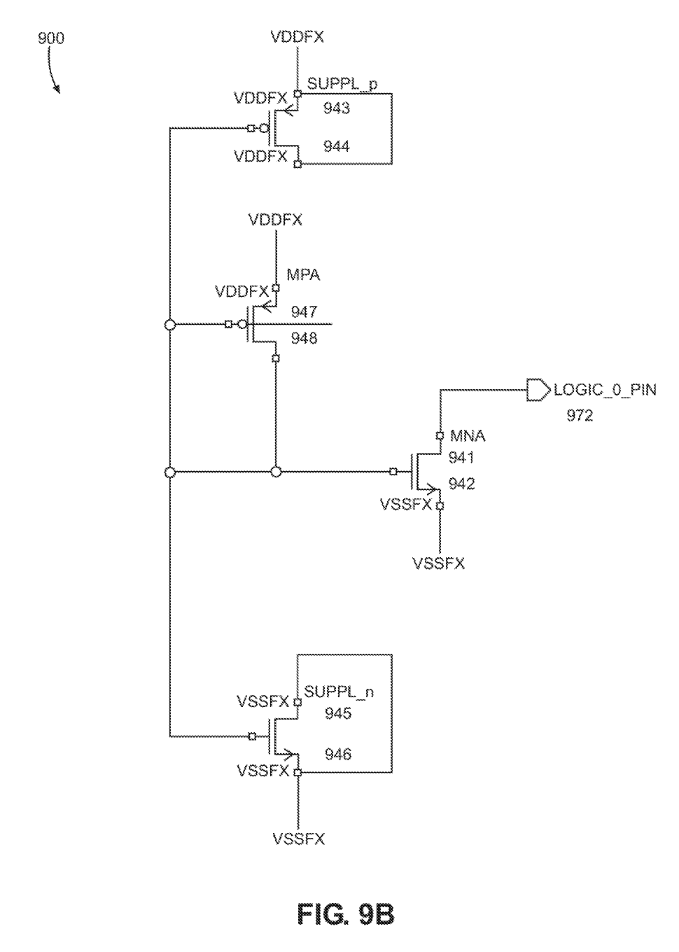

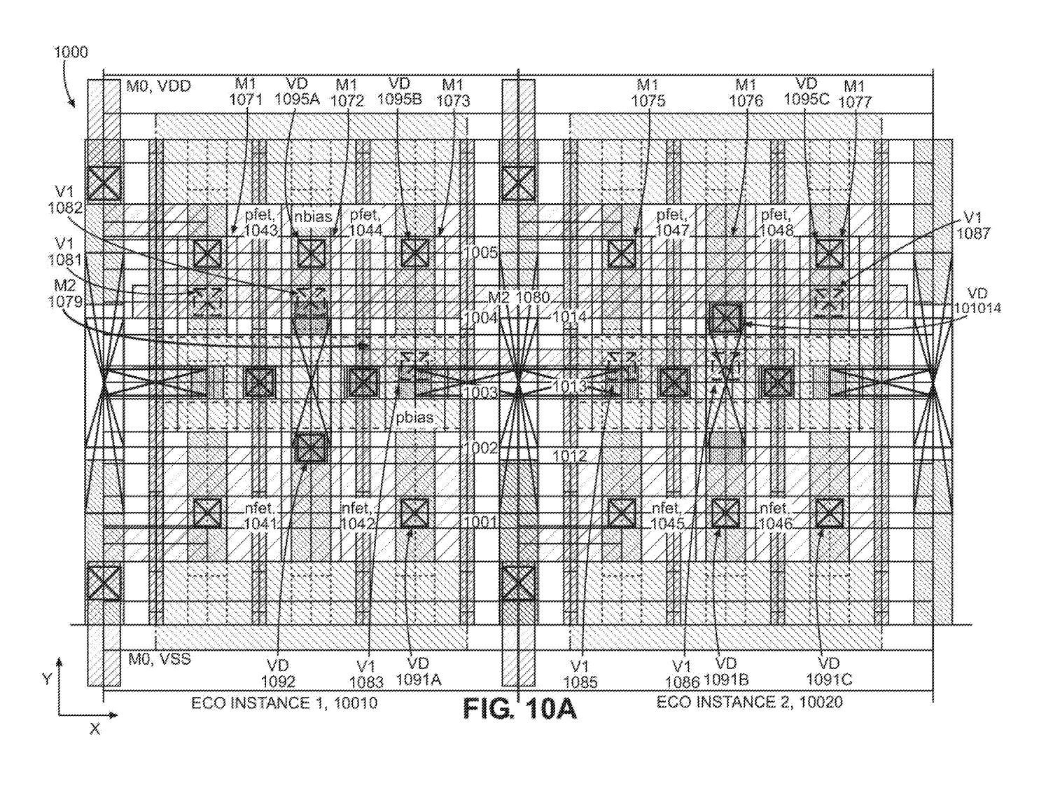

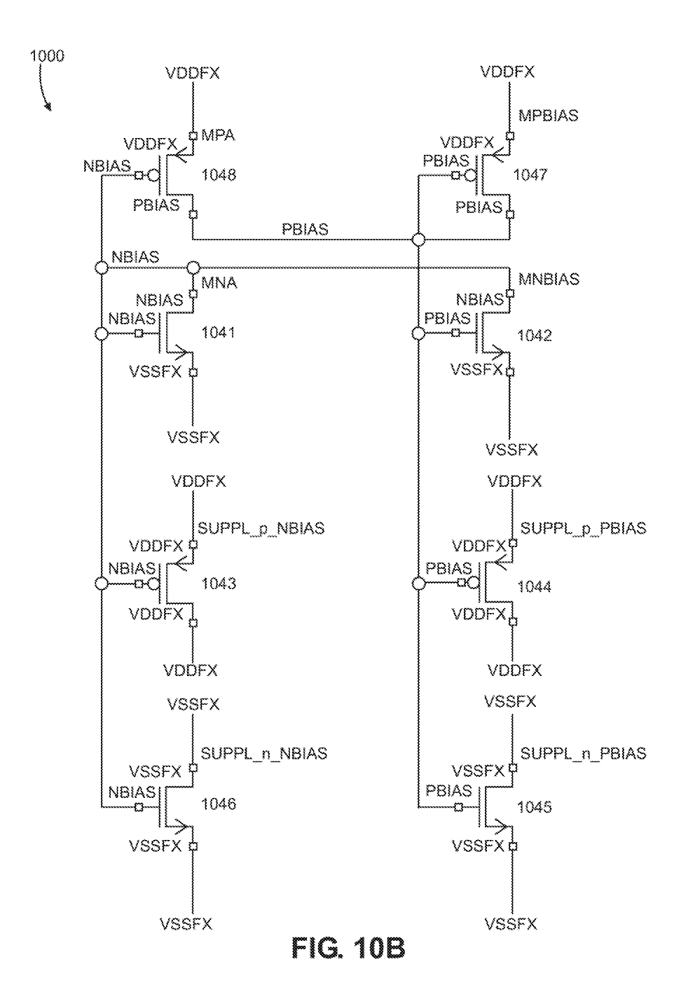

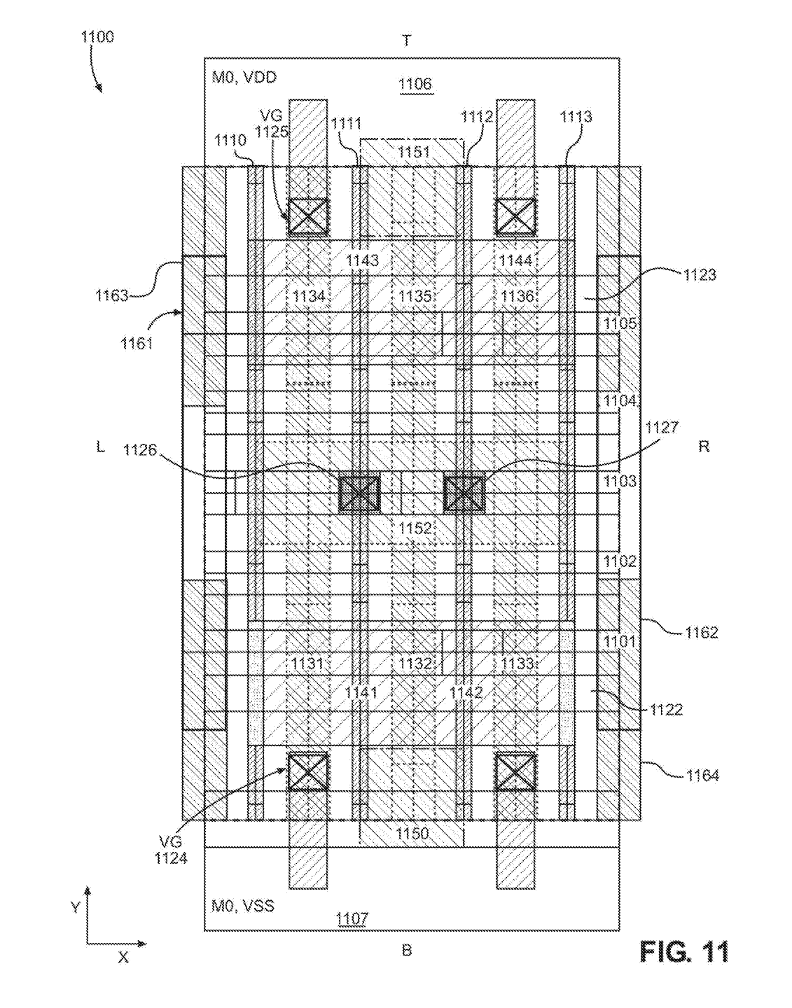

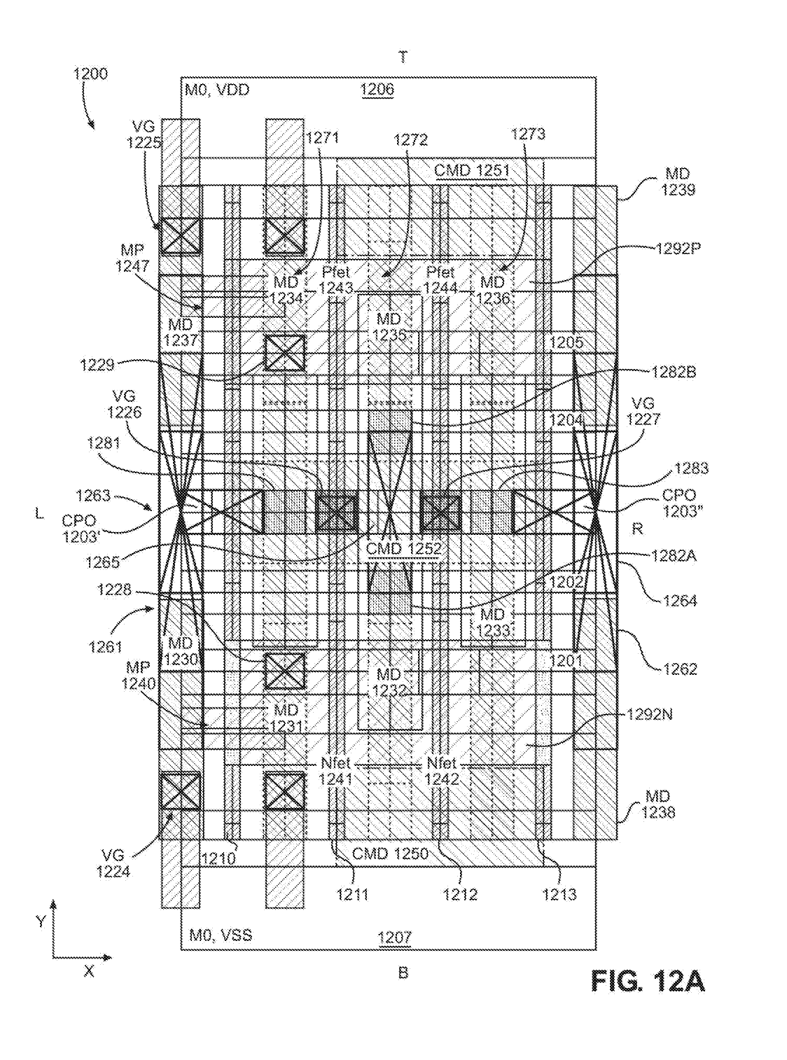

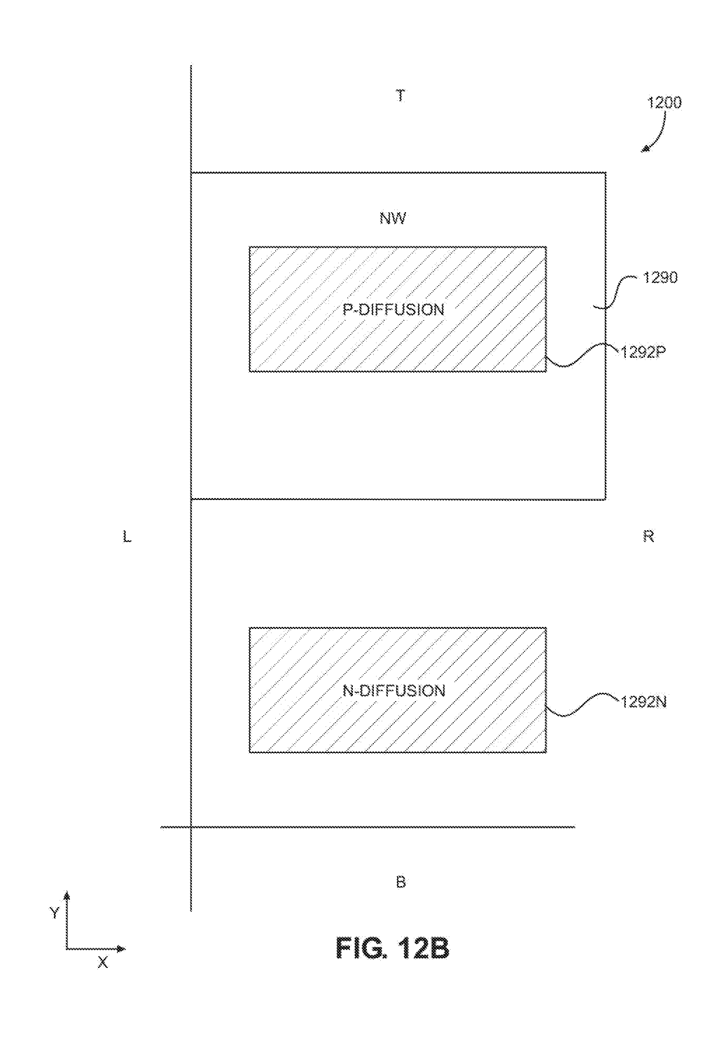

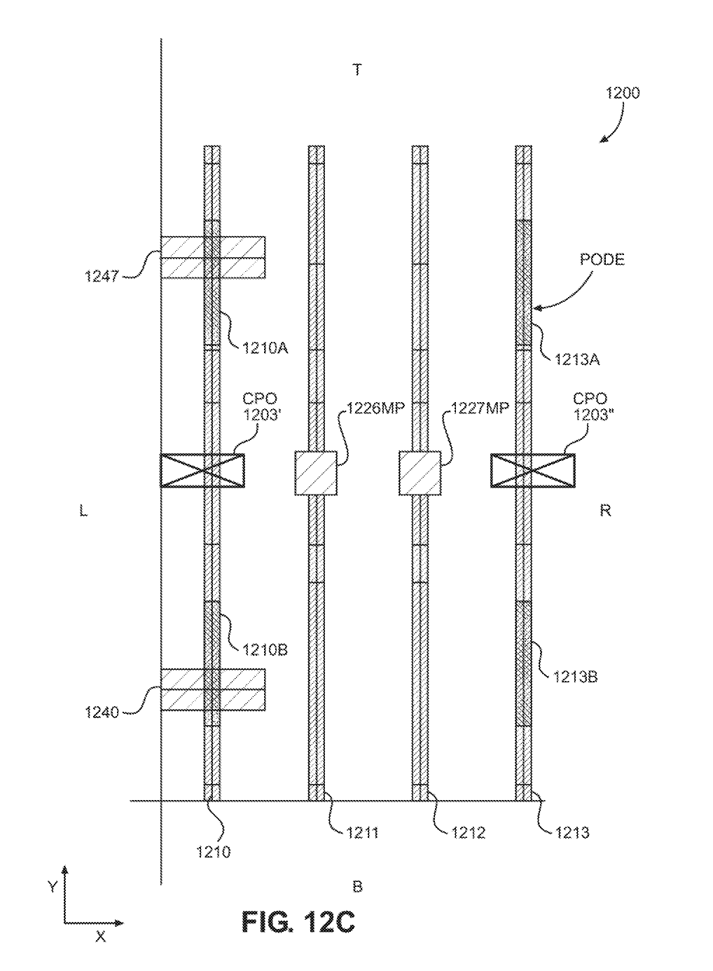

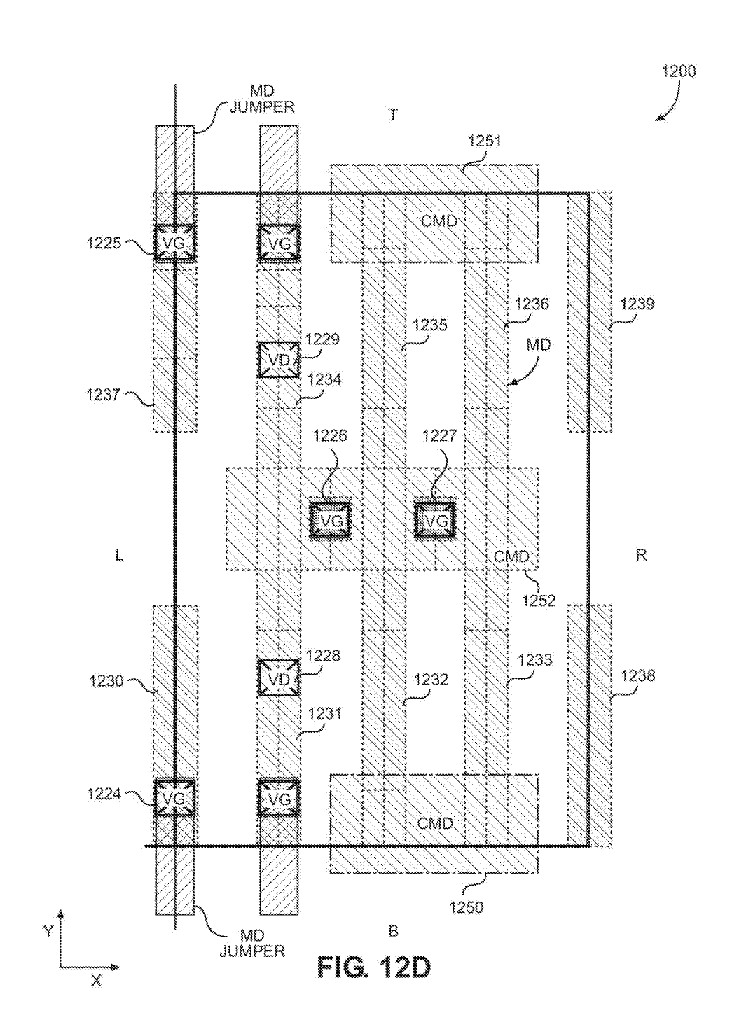

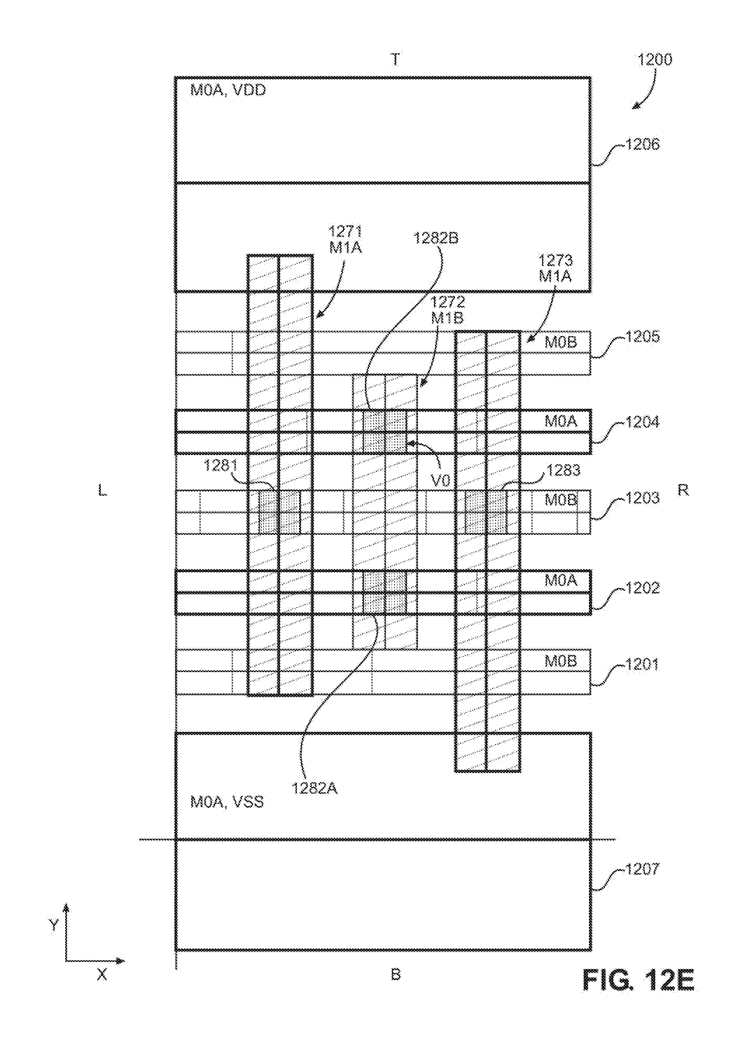

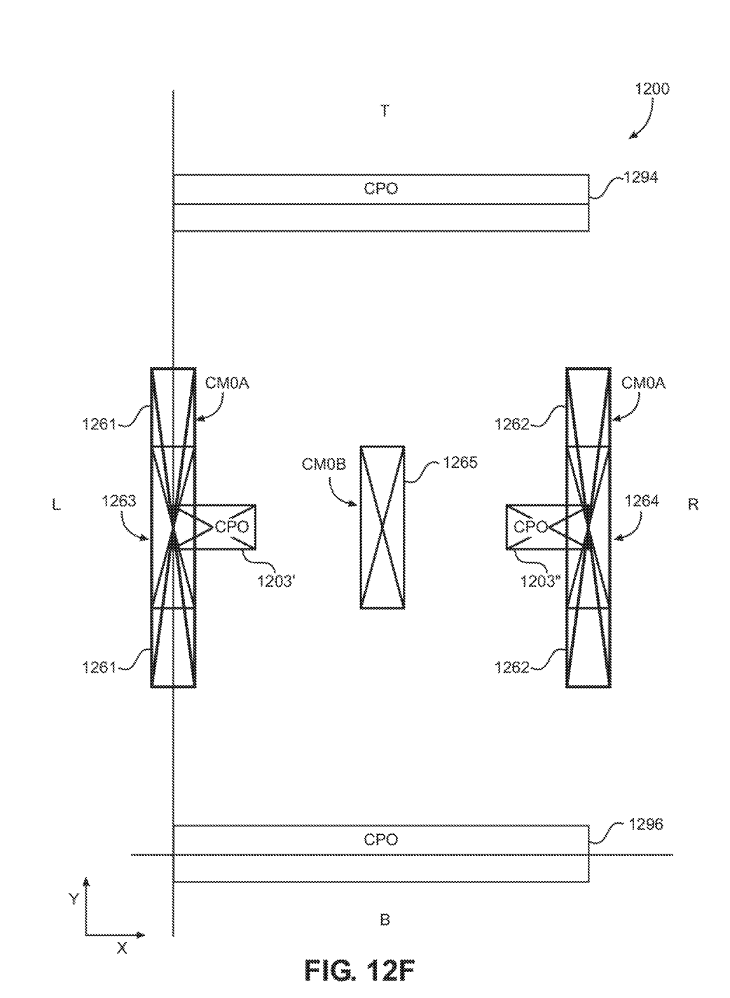

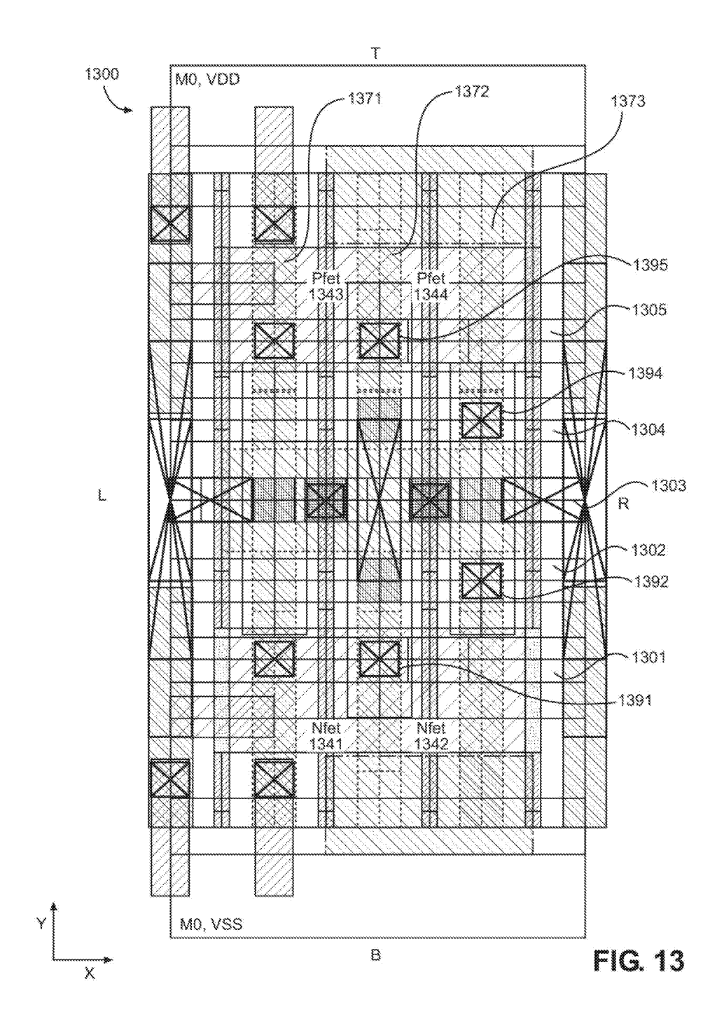

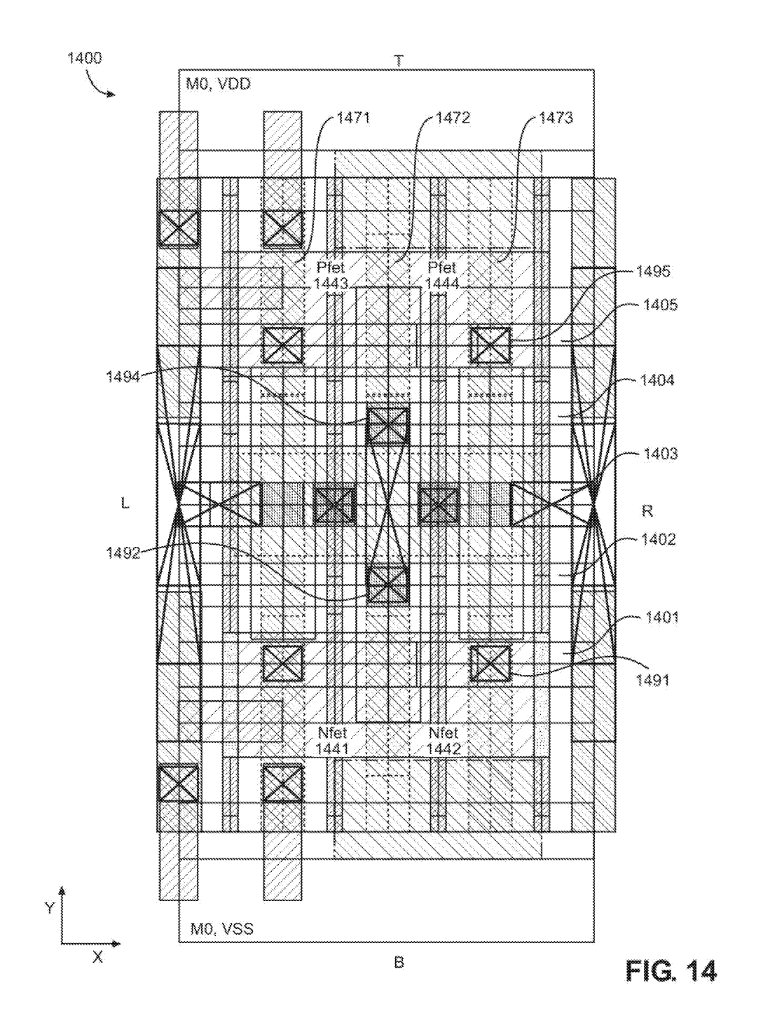

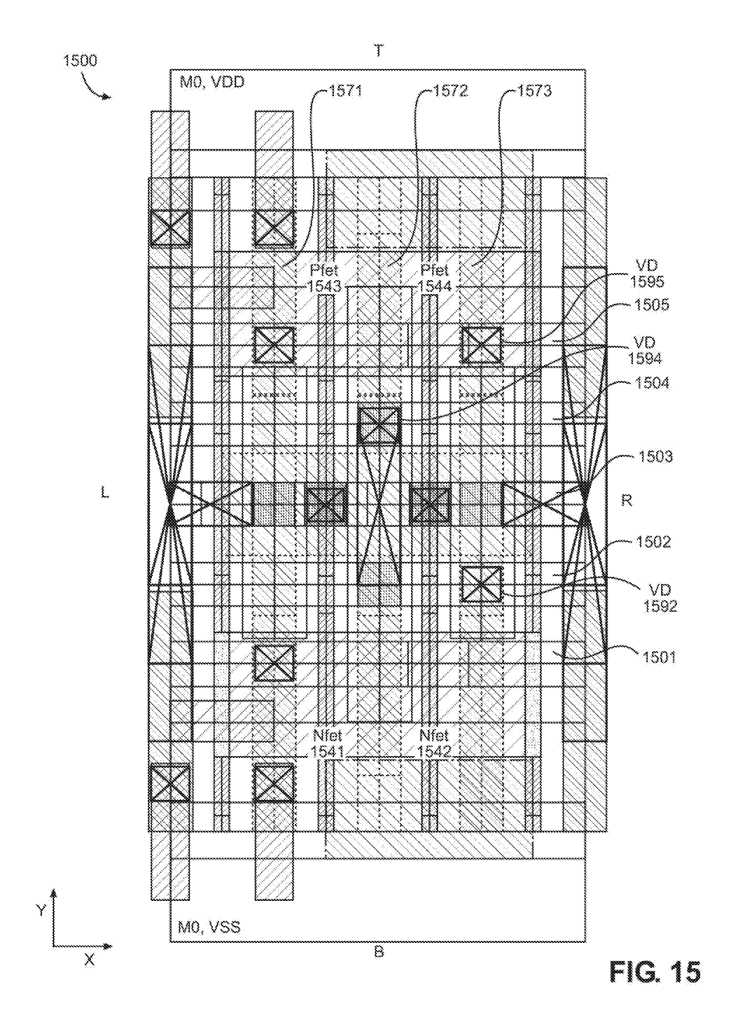

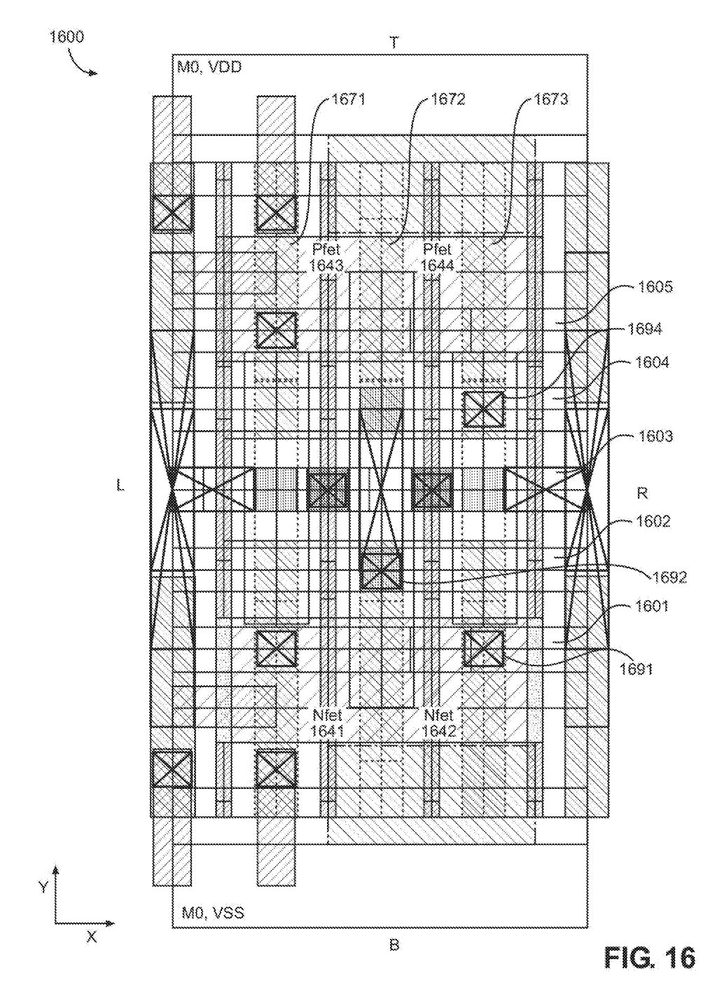

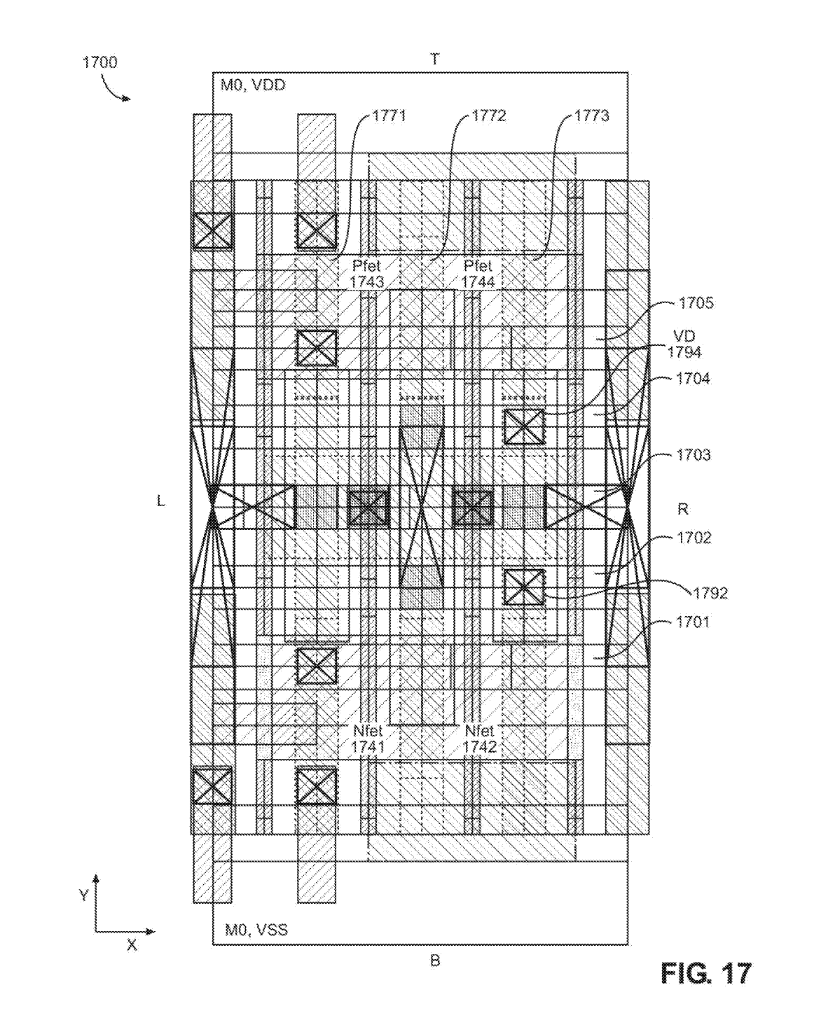

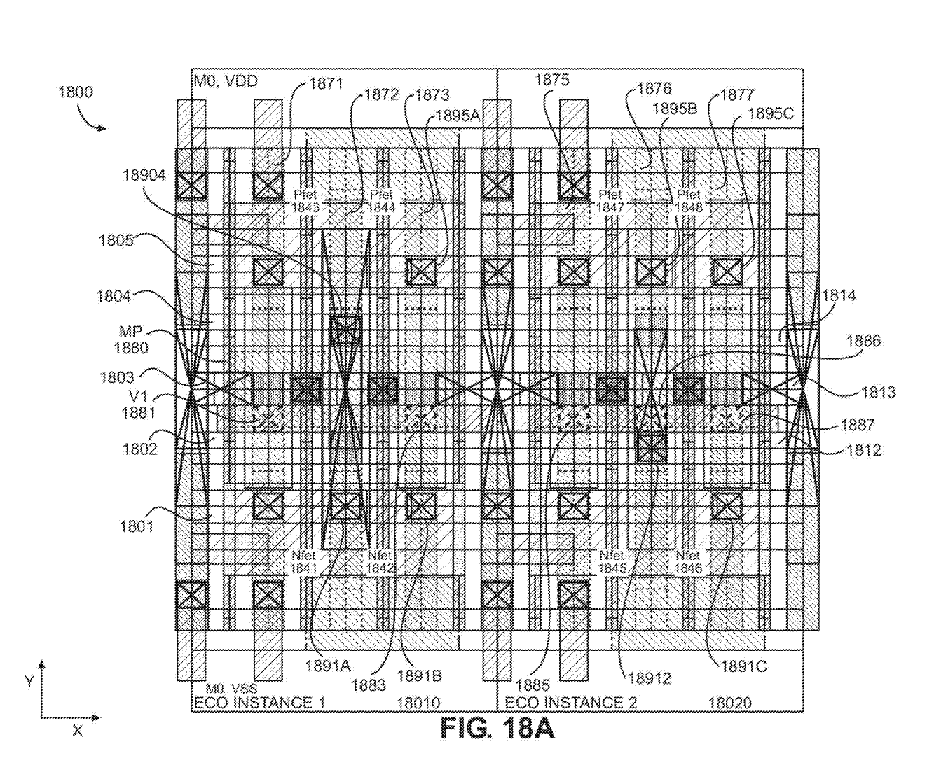

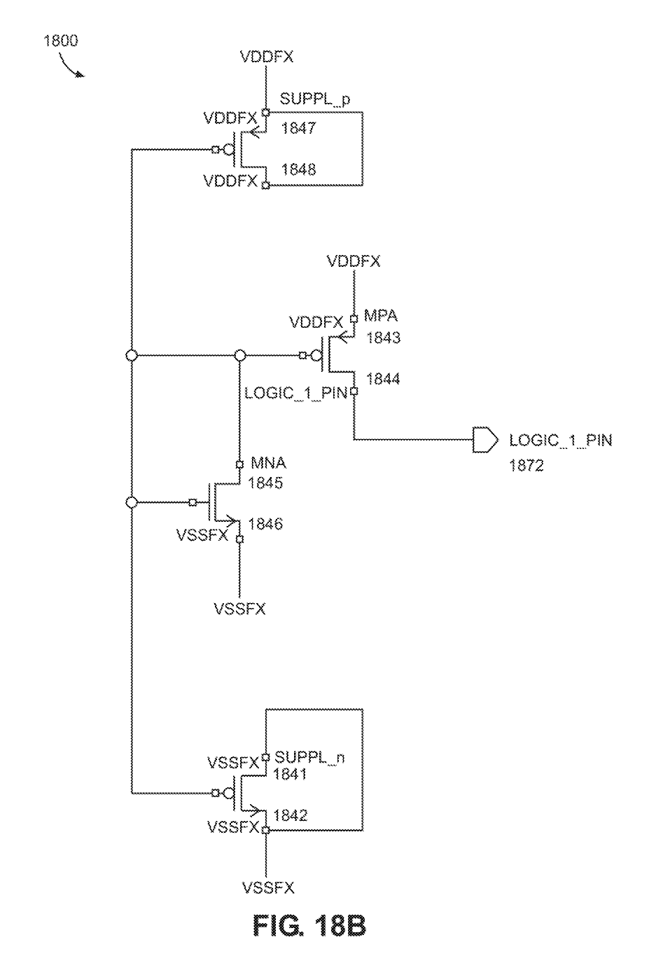

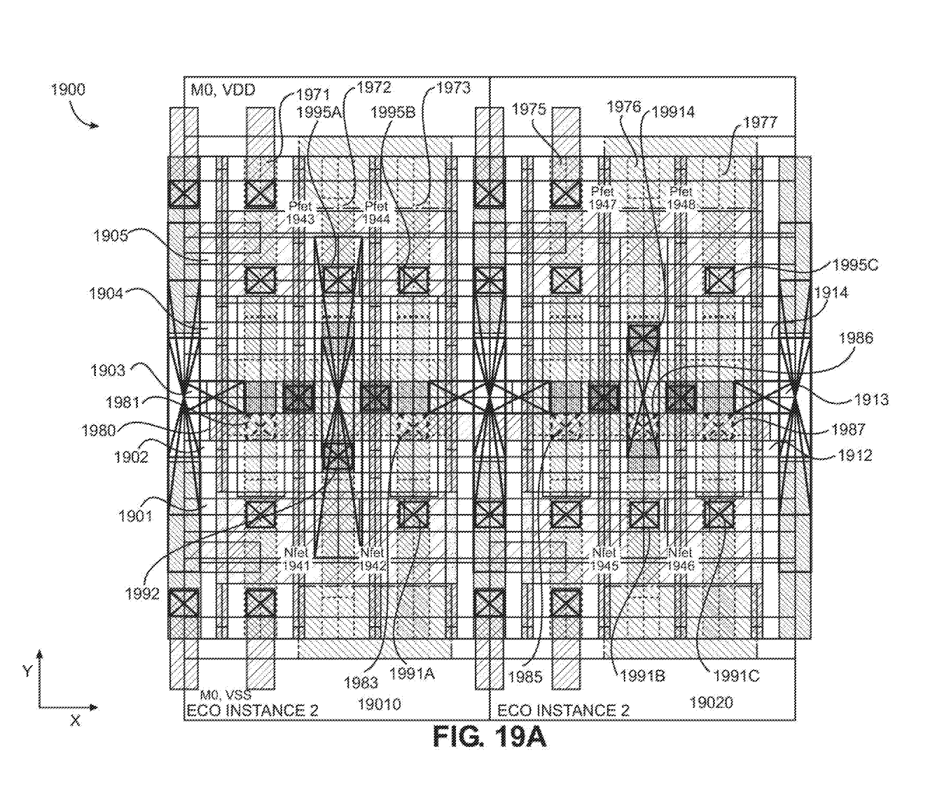

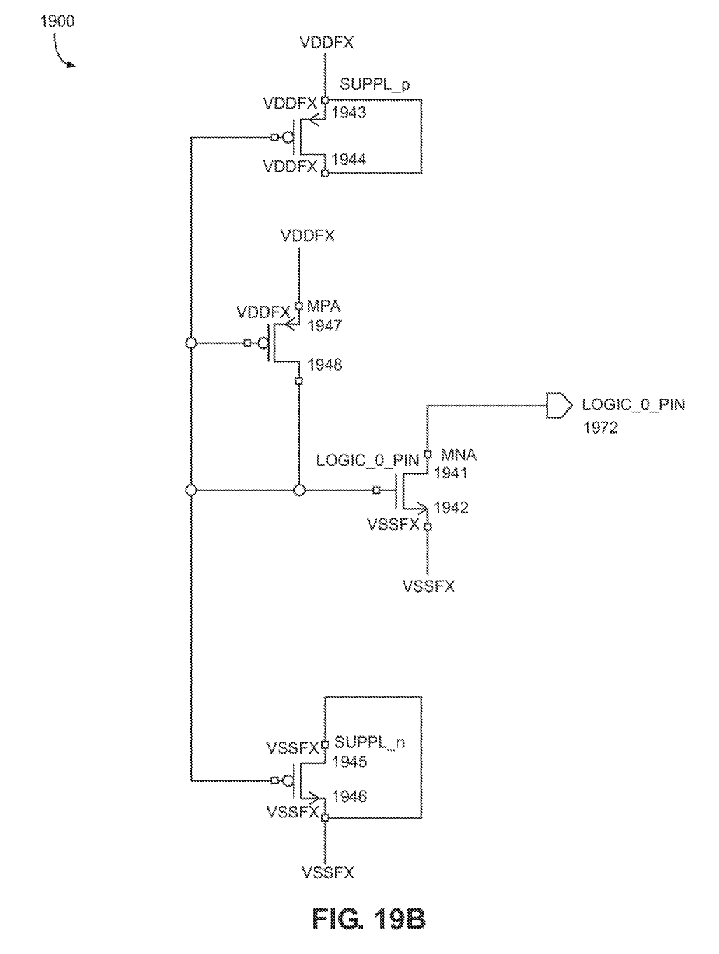

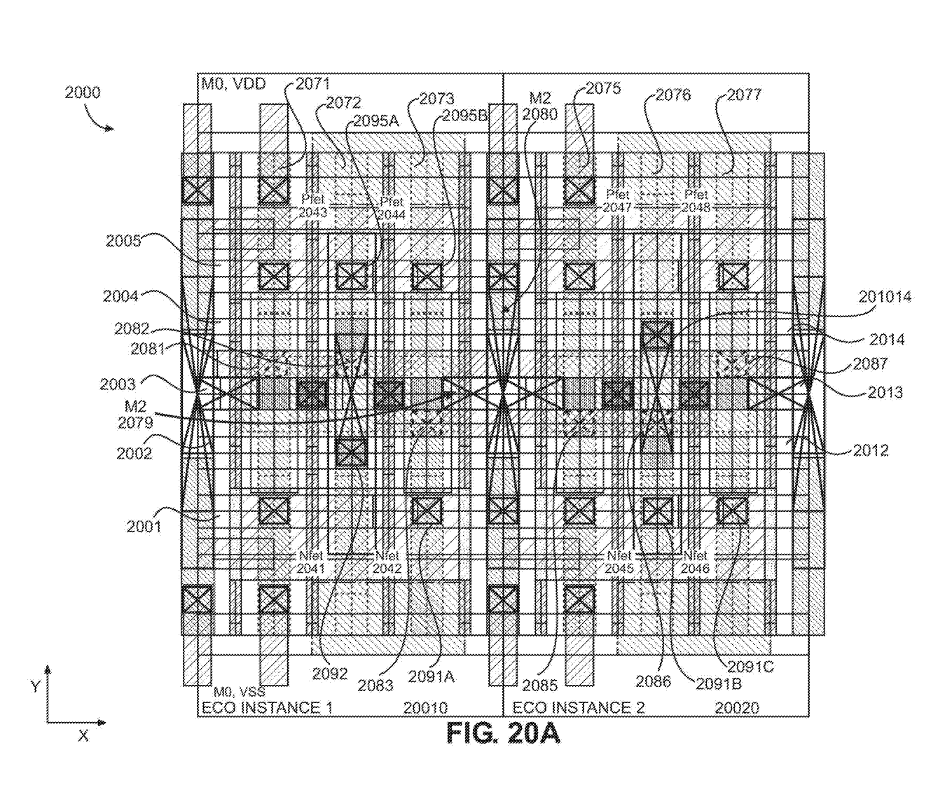

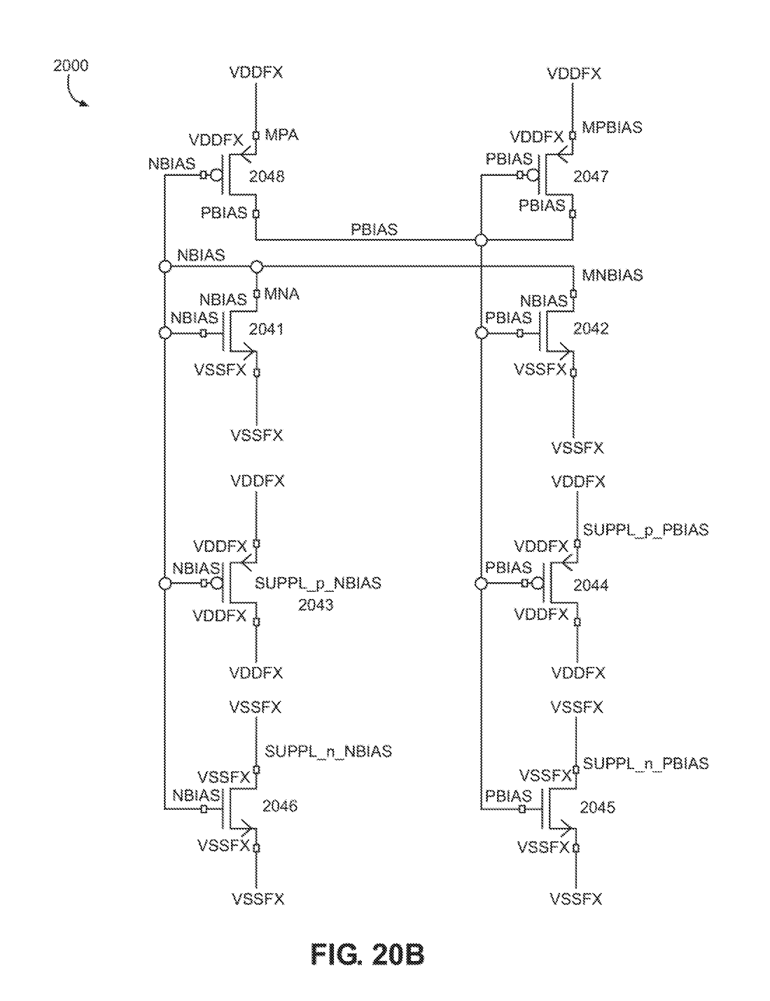

FIG. 8A illustrates a tie-high circuit 800 using two ECO cells 200 while FIG. 8B provides a schematic view of the tie-high circuit 800. In particular, the tie-high circuit 800 includes a first ECO cell 8010, which has NFETs 841 and 842 as well as PFETs 843 and 844. A second ECO cell 8020 has NFETs 845 and 846 and PFETs 847 and 848. The Mi tracks in the first ECO cell 8010 are labeled as 871-873 while those in the second ECO cell 8020 are labeled as 875-877. M0 tracks 801 and 805 are continuous across both the ECO cells 8010 and 8020. M0 tracks 802, 803, and 804 within the first ECO cell 8010 are isolated from M0 tracks 812, 813, and 814 in the second ECO cell 8020 by the cutouts CM0A 261 and 262 and CM0B 263 and 264 described in FIG. 2F.

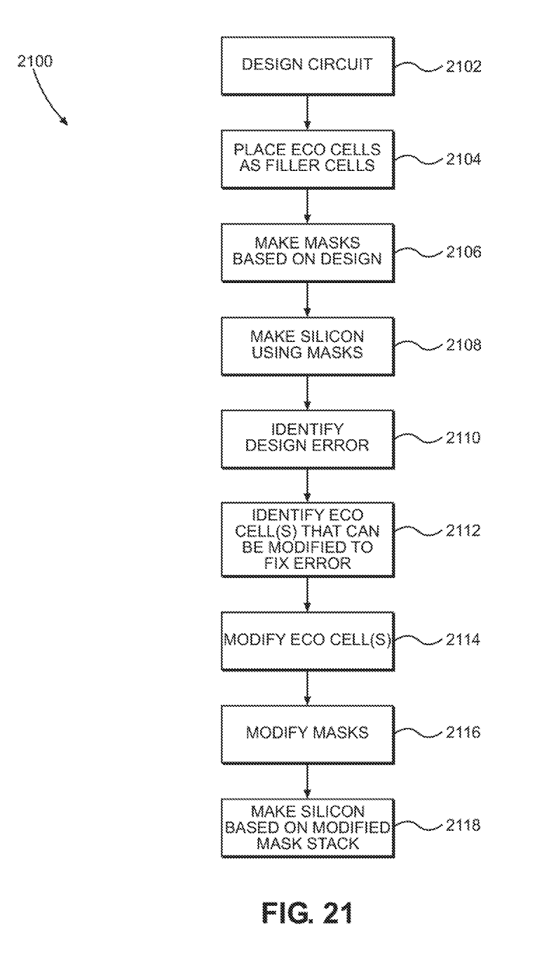

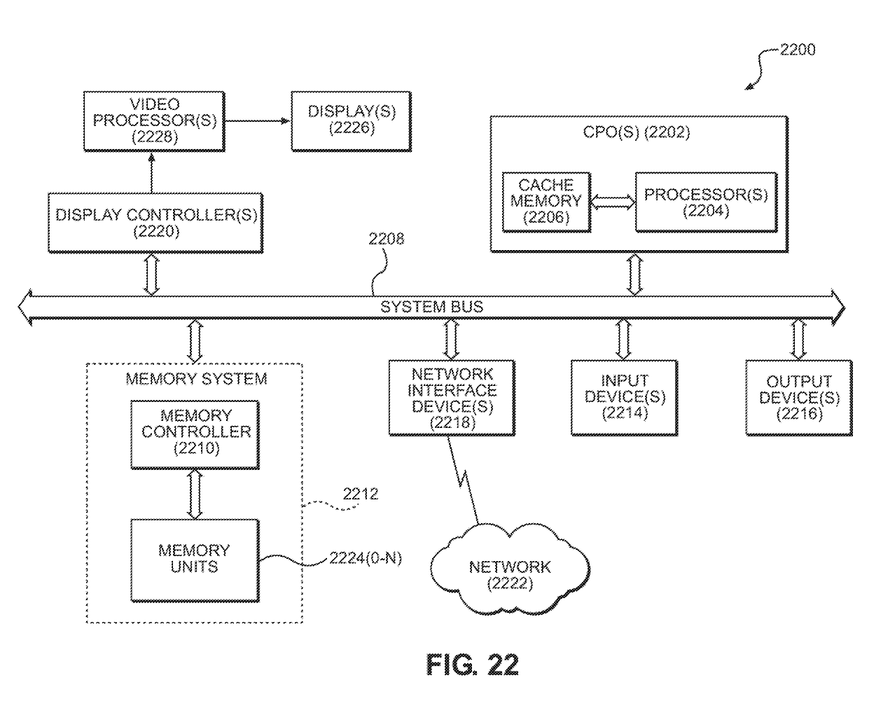

With continued reference to FIGS. 8A and 8B, a supplemental NFET device (suppl_n) is a pair of NFETs 841 and 842, and a supplemental PFET device (suppl_p) is a pair of PFETs 847 and 848. The sources and drains of the NFETs 841 and 842 are connected to VSS through VD vias 891A and 891B. The sources and drains of the PFETs 847 and 848 are connected to VDD through VD vias 895B and 895C. The PFETs 843 and 844 are associated with a transistor MPA of FIG. 8B, and the NFETs 845 and 846 are associated with a transistor MNA of FIG. 8B. All the transistors shown in FIG. 8B have common gate connections. These connections are made by the addition of M2 shape 880 and V1 vias 881, 883, 885, 886, and 887. V1 via 886 connects the outputs of the MNA NFETs 845 and 846 to all the device gates in the ECO cells 8010 and 8020. VD via 8912 connects the drains of the parallel NFETs 845 and 846 to the M0 track 812 through the V1 via 886 to the M2 shape 880. The source of the NFET 846 is connected to VSS through VD via 891C. The drain of the PFET 844 is connected to VDD through VD via 895A. The source of the PFET pair 843 and 844 (MPA in FIG. 8B) is connected to the M0 track 804 through VD via 8904 and is the output of the tie-high circuit 800. That is, M1 track 872 is the tie-up output (logic_1_pin in FIG. 813). M1 tracks 871, 873, 875, 876, and 877 are all connected together by the M2 shape 880.

Thus, the tie-high circuit 800 is accomplished by a pair of ECO cells 200 with the addition of the VD vias 891A, 891B, 891C, 895A, 895B, 895C, 8904, and 8912, and the V1 vias 881, 883, 885, 886, and 887 as well as the M2 shape 880. While this requires changes on three mask layers, the more complex functionality of the tie-high circuit 800 is still effectuated with minimal changes to the mask stack. Further, these changes still occur relatively deep in the MEOL stack.

Similarly, FIGS. 9A and 9B illustrate a tie-low circuit 900 formed from two ECO cells 200. The tie-low circuit 900 generally requires only PFET MPA and NFET MNA. The supplemental elements are available with the ECO cells 200. In particular, FIG. 9A illustrates ECO cell 9010 with NFETs 941 and 942 and PFETs 943 and 944 as well as M1 tracks 971-973. ECO cell 9020 includes NFETs 945 and 946 and PFETs 947 and 948 as well as M1 tracks 975-977. M0 tracks 901 and 905 are continuous across both the ECO cells 9010 and 9020. M0 tracks 902, 903, and 904 are isolated from M0 tracks 912, 913, and 914 by the cutouts CM0A 261 and 262 and CM0B 263 and 264 described in FIG. 2F.

With continued reference to FIGS. 9A and 9B, the supplemental NFET device (suppl_n) is a pair of NFETs 945 and 946, and the supplemental PFET device (suppl_p) is a pair of PFETs 943 and 944. The sources and drains of the NFETs 945 and 946 are connected to VSS through VD vias 991B and 991C. The sources and drains of the PFETs 943 and 944 are connected to VDD through VD vias 995A and 995B. The PFETs 947 and 948 are the associated with transistor MPA of FIG. 9B, and the NFETs 941 and 942 are associated with transistor MNA of FIG. 9B. PFET 948 is coupled to VDD through VD via 995C. All the transistors shown in FIG. 9B have common gate connections. These connections are made by the addition of M2 shape 980 and V1 vias 981, 983, 985, 986, and 987. V1 via 986 connects the outputs of the MPA PFETs 947 and 948 to all the device gates in the ECO cells 9010 and 9020. VD via 9914 connects the drain of the parallel PFETs 947 and 948 to the M0 track 914 through the V1 via 986 to the M2 shape 980. The source of the NFET 942 is connected to VSS through VD via 991A. The drains of NFETs 941 and 942 are connected to the output through added VD via 992. The source of the PFET pair 947 and 948 (MPA in FIG. 9B) is connected to the M0 track 914 through VD via 9914. That is, M1 track 972 is the tie-low output (logic_)_pin in FIG. 9B). M1 tracks 971, 973, 975, 976, and 977 are all connected together by the M2 shape 980.

Thus, the tie-low circuit 900 is accomplished by a pair of ECO cells 200 with the addition of the VD vias 991A, 991B, 991C, 995A, 995B, and 995C, and the V1 vias 981, 983, 985, 986, and 987 as well as the M2 shape 980. While this requires changes on three mask layers, the more complex functionality of the tie-low circuit 900 is still effectuated with minimal changes to the mask stack. Further, these changes still occur relatively deep in the MEOL stack.

Another possible function is a decoupling capacitor (DCAP). DCAPs are often used in filler space. Since the interconnections and/or arrangement of mask shapes are optimized for the standard cell like other logic functions, it is not always easy to convert a DCAP to another function without extensive mask changes. However, exemplary aspects of the present disclosure allow ready conversion from the ECO cell 200 to a DCAP as well as the ability to change the DCAP to the ECO cell 200 without extensive mask work.

FIGS. 110A and 10B illustrate a two-cell DCAP circuit 1000 with an accompanying schematic diagram in FIG. 10B. FIG. 10B illustrates the DCAP circuit 1000 in a configuration such that no FET gate is tied directly to VDD or VSS. Further, the DCAP circuit 1000 only requires PFET and NFET devices labeled as MPA, MPBIAS, MNA, and MNBIAS. Supplemental devices are included to afford the layout using the ECO cells 200.

With the knowledge of how the DCAP circuit 1000 is laid out, it is readily able to be translated into using the ECO cells 200. In particular, two ECO cells 10010 and 10020 are used. The ECO cell 10010 has NFETs 1041 and 1042 and PFETs 1043 and 1044. Similarly, the ECO cell 10020 has NFETs 1045 and 1046 and PFETs 1047 and 1048. M1 tracks 1071-1073 are used in ECO cell 10010. M1 tracks 1075-1077 are used in the ECO cell 10020. M0 tracks 1001 and 1005 are continuous across both the ECO cells 10010 and 10020 to provide a continuous VSS and VDD, respectively. M0 tracks 1002, 1003, and 1004 are isolated from M0 tracks 1012, 1013, and 1014 by cutouts CM0A 261 and 262 and CM0B 263 and 264 as previously explained. Mapping FIG. 10A to the elements in FIG. 10B shows that the NFET 1041 is MNA; the NFET 1042 is :MNBIAS; the NFET 1045 is Suppl n_n_pbias, the NFET 1046 is Suppl_n_nbias; the PFET 1043 is Suppl_p_nbias; the PFET 1044 is Suppl_p_pbias; the PFET 1047 is MPBIAS; and the PFET 1048 is MPA.

With continued reference to FIGS. 10A and 10B, the ECO cells 200 are further modified by the addition of M2 shape 1079, which provides interconnections through added V1 vias 1083, 1085, and 1086 to the M1 tracks 1073, 1075, and 1076, respectively. This arrangement forms the pbias metal network. Likewise, the ECO cells 200 are further modified by the addition of M2 shape 1080, which provides interconnections through added V1 vias 1081, 1082, and 1087 to the M1 tracks 1071, 1072, and 1077, respectively. This arrangement forms the nbias metal network. To complete all the source and drain connections, VD vias 1091A, 1091B, 1091C, 1092, 1095A, 1095B, 1095C, and 101014 are also added.

Thus far, illustrations have shown the lateral placement of ECO cells to create advanced functions, but multi-row or stacked realizations that employ the ECO standard cells are also specifically contemplated and within the scope of this disclosure. For example, referring back to FIG. 10A wherein the DCAP circuit 1000 was realized as a lateral arrangement of ECO cells, a vertical stacking of ECO cells may realize the same function. This can be accomplished by maintaining the placement of the ECO cell 10010 as is with the same orientation and same x, y location and the same VD via customizations (also referred to as personalizations) and placing the ECO cell 10020, having the same VD via personalizations as the ECO cell 10020 in FIG. 10A, but with an orientation that is mirror flipped along the x-axis and has a y-offset consistent with the cell height, thereby sharing the M0 VDD track. The M1 tracks in the ECO cells 10010 and 1002.0 are now vertically aligned with each other. That is, M1 track 1075 is vertically above and aligned to M1 track 1071, M1 track 1076 is above and vertically aligned with M1 track 1072, and finally, M1 track 1077 is above and vertically aligned with M1 track 1073. Since the instantiations are now vertically stacked, additional M1 segments are added to connect to M1 tracks 1071 and 1075, and M1 tracks 1073 and 1077, respectively. These added M1 segments connect each of the respective inputs in the ECO cell 10010 and the ECO cell 10020. The M2 shape 1080 which made connections to the M1 tracks 1071, 1072, and 1077 through the V1 vias 1081, 1082 and 1087, respectively, is now modified to only make connections to the M1 tracks 1071 and 1072 through the V1 vias 1081 and 1082, respectively. The M2 shape 1079 which formerly made connections to the M1 tracks 1073, 1075, and 1076 through the V1 vias 1083, 1085, and 1086, respectively is now modified to only make connections within the ECO cell 10020 (the top mounted cell) to the M1 tracks 1076 and 1077 through the V1 vias 1083 and 1087, respectively. Using the above described modifications and placements, a multi-row realization of the DCAP circuit 1000 may be realized. Approaches like those described above allow ECO realizations to be crafted using fewer lateral poly-pitches albeit with additional total height. While discussed in the present paragraph for the ECO cell architecture, it can also be readily applied to an Ultra High Performance (UHP) ECO architecture as discussed below, and for other architectures described with respect to the present disclosure, as will be recognized by those having skill in the art.

Thus, with relatively few ECO cells, and relatively few changes to a few levels of masks, more complex functionality is able to be created to correct design defects. The few mask changes are relatively deep in the MEOL, which also improves redesign time.

FIGS. 3-10 have demonstrated the means to craft ECO compliant cells using the ECO cell 200 of FIG. 2A. The ECO cell 200 allows plug-and-play with the cells having a standard cell structure that is readily modified to provide new functions. The ECO cells can be used as a filler for pattern density or may be programmed with minimum mask changes that occur deep in the MEOL to implement a design change.

The ECO cell 200 of FIG. 2A is based on the logic cell 100 of FIG. 1. However, other cells may also be used depending on node size, cell size, and the like. For example, FIG. 11 illustrates a conventional logic cell 1100 that may be characterized as a UHP cell. The logic cell 1100 differs from the logic cell 100 in that the logic cell 1100 has a taller cell height (e.g., 360 nm) that supports larger fin count devices, but is organized substantially the same as the logic cell 100. While the same number of M0 tracks are used, the spacing and width of the M0 tracks may be varied relative to the logic cell 100 in view of the different height. The edge M0 VDD and VSS rails may also be larger to support increased current used to support higher device fin counts.

The logic cell 1100 includes five (5) signal wires, M0 tracks 1101-1105, running on an M0 mask layer in a lateral direction (i.e., L or R (or R to L)). The top (T) of the logic cell 1100 has an edge with a shared power line (VDD), M0 track 1106, running laterally across the logic cell 1100 on the M0 layer. The bottom (B) of the logic cell 1100 has an edge with a shared ground (VSS), M0 track 1107, running laterally across the logic cell 1100 on the M0 layer. The logic cell 1100 has polysilicon shapes 1110-1113 running orthogonal to the M0 tracks (i.e., from T to B (or B to T)). Polysilicon shapes 1111 and 1112 are associated with NFETs 1141 and 1142 and PFETs 1143 and 1144 formed by the intersection of diffusion shapes 1122 and 1123 with the polysilicon shapes 1111 and 1112. Polysilicon shape 1110 is proximate edge L and a left edge of the diffusion shapes 1122 and 1123 while polysilicon shape 1113 is proximate edge R and a right edge of the diffusion shapes 1122 and 1123. As illustrated, the polysilicon shapes 1110 and 1113 do not form any devices. Polysilicon shapes 1110 and 1113 are sometimes referred to as PODE and are inset one-half a poly-to-poly and diffusion-to-diffusion ground rule space from the left edge L and the right edge R of the logic cell 1100 to ensure no connectivity between adjacently-related cells.

With continued reference to FIG. 11, MD shapes 1131-1136 provide overlays to the diffusion shapes 1122 and 1123 to reduce diffusion resistance while allowing connection to the M0 tracks (i.e., 1101-1107). VD vias provide a means to connect the MD layer to the M0 layer (none shown). Sometimes VG vias, which are normally used to connect a polysilicon gate to the M0 layer through an MP layer, can be used to make M0 connections to the MD layer. Thus, as illustrated, VG vias 1 124 and 1125 are used to connect the MD shape 1131 and MD shape 1134 to the M0 track 1107 and the M0 track 1106, respectively. In this manner, VSS and VDD are coupled to the MD shape 1131 and MD shape 1134, respectively. VG vias 1126 and 1127 overlay MP shapes thereby making connections to polysilicon gates of the FETs 1141, 1143 and 1142, 1144, respectively, and connections to M0 track 1103.

With continued reference to FIG. 11, the logic cell 1100 further includes CMD shapes 1150 and 151, which are located along the bottom and the top of the logic cell 1100 respectively. The CMD shapes 1150 and 1151 are cuts that ensure no MD connections between adjoining cells to the top or the bottom of the logic cell 1100. CMD shape 1152, located in the ‘center,’ is a cut that isolates the MD shapes 1131-1133 from the M1) shapes 1134-1136. Further, the CMD shape 1152 also isolates MP shapes located on the polysilicon shapes 1111 and 1112. The center CMD shape 1152 must be applied over the MP shapes connecting to the polysilicon gates to ensure no shorting between the MD and MP layers. Depending on the logic function being realized by the logic cell 1100, the center CMD shape 1152 may be customized.

Since there are no direct MD connections between the source/drains (created by the diffusion shape 1122) of the NFETs 1141 and 1142 and the source/drains (created by the diffusion shape 1123) of the PFETs 1143 and 1144, all connections to the metal layers are made on the M1 layer running vertically in parallel to the polysilicon shapes 1111 and 1112. While not shown in FIG. 11, these M1 shapes will provide connections between the M0 and M1 layers through V0 vias. Connections between the MD and M0 layers will be made with VD/VG vias, as was shown for the power and ground connections.

Like the CMD shapes which were used to cut the MD layer to ensure no connectivity along the top and the bottom and within the logic cell 1100 as needed, CPO shapes perform a similar function with respect to elements in the poly layer. A CM0 set of shapes is employed along the cell left/right boundaries to ensure no lateral connectivity between cells on the M0 layer. These shapes, like many others, can be multi-patterned to afford the best lithography. The M0 shapes are one such set that are multi-patterned. In FIG. 11, the M0 shapes associated with the M0 tracks 1101, 1103, and 1105 belong to one pattern set while the M0 shapes associated with the M0 tracks 1102, 1104, 1106, and 1107 belong to another pattern set. Since the M0 layer is dual-patterned, it stands to reason that the CM0 shapes are dual-patterned as well. In FIG. 11, the left and right edges of the logic cell 1100 have CM0 patterns CM0A 1161 and 1162 and CM0 patterns CM0B 1163 and 1164 to ensure no left/right connectivity on the M0 layer between cells to the left or right. Like the use of CMD shapes within the cell ‘center,’ CM0A and CM0B shapes can do the same for the respective M0 shapes.

MD shapes on the border of the logic cell 1100 and are shared across the boundary of laterally-placed cells. These MD shapes are analogous to the MD shapes 130, 137, 138, and 139 in FIG. 1 and are used for pattern matching such that there is no gap in the MD utilization across cell boundaries.

Much like the logic cell 100 of FIG. 1 was modified to make the ECO cell 200 of FIG. 2A, the logic cell 1100 of FIG. 11 may be modified to make a UV ECO cell 1200, illustrated in FIGS. 12A-12F. Again, recognizing that FIG. 12A is visually busy, FIGS. 12B-12F provide exploded views of layers isolated from one another to facilitate understanding of the UHP ECO cell 1200. As with the ECO cell 200, in the UHP ECO cell 1200, the arrangement of the poly, M0, and CPO layers are the same relative to the logic cell 1100. The location of the VG vias does change between the logic cell 1100 and the UHP ECO cell 1200. In particular, VG vias 1224 and 1225 are located on the same MD shapes as the logic cell 1100, but additional VG vias 1227 and 1226 are located on MD shapes 1230 and 1237, respectively. These additional vias are associated with the shared left edge. Thus, the VSS M0 rail connects to MD shapes 1230 and 1231 while the VDD M0 rail connects to MD shapes 1234 and 1237. A further change from the logic cell 1100 is that MP jumpers 1240 and 1247 provide connections from the MD shapes 1230 and 1237 to the MD shapes 1231 and 1234, respectively.

As illustrated, the ECO cell 1200 has an N-well 1290 (illustrated in FIG. 12B) in which a p-type diffusion region 1292P is formed. The ECO cell 1200 further has an n-type diffusion region 1292N (see FIG. 12B for these elements in isolation). The N-well 1290 and diffusion regions 1292N and 1292P are the lowest level and formed in or on the lowest substrate level generally. The diffusion regions 1292P and 1292N are wide enough in the x-axis direction (L to R or R to L) to support four poly pitches (e.g., polysilicon shapes 1210-1213, better illustrated in FIG. 12C). Again, it should be appreciated that other widths that are integer multiples of poly pitches may be used. However, for consistency, ECO cell 1200 is four poly pitches wide.

FIG. 12C illustrates the four polysilicon shapes 1210-1213. Polysilicon shapes 1210 and 1213 are sometimes referred to as PORE and are inset one-half a poly-to-poly and diffusion-to-diffusion ground rule space from the left edge L and the right edge R of the ECO cell 1200 to ensure no connectivity between adjacently-related cells. The MP shapes 1240 and 1247 are sometimes referred to as jumpers because MP shapes 1240 and 1247 provide connections from the MD shapes 1230 and 1237 to MD shapes 1231 and 1234, respectively. The MP shapes 1240 and 1247 also connect to the left edge polysilicon shape 1210 at the PODE boundary. Also illustrated in FIG. 12C are MP shapes 1226MP and 1227MP, which reflect that the MP layer is present to provide electrical connections for the VG vias 1226 and 1227, respectively to polysilicon shapes 1211 and 1212, respectively. CPO rectangular shapes 1203′ and 1203″ are also illustrated on top of polysilicon shapes 1210 and 1213, respectively, thereby splitting each of the respective polysilicon shapes into two separate pieces. Regions 1210A, 1210B, 1213A, and 1213B on the polysilicon shapes 1210 and 1213 reflect where the polysilicon shapes 1210 and 1213 meet the diffusion edge of PODE. Polysilicon shapes 1211 and 1212 lie interiorly of the diffusion edge.

FIG. 12D illustrates the MD, CMD, VG, and VD layers. In particular, the NM layer includes MD shapes 1230-1239 formed in part by cut shapes CMD 1250-1252. VD vias 1228 and 1229 are coupled to the MD shapes 1231 and 1234, respectively. Similarly VG vias 1224-1227 provide connections as better explained below. MD jumpers allow two cells that share a common MD with a common set of VG vias (e.g., VG vias 1224 and 1225). If the two cells align such that their power and ground VG contacts are vertically aligned to one another, then a post-processing algorithm can allow them to share a larger centrally-located via in the center of the power rail if desired.

FIG. 12E illustrates the M0, V0, and M1 layers. In particular, M0 tracks 1206 and 1207 form VDD and VSS rails, respectively. M0 tracks 1201, 1202, 1203, 1204, and 1205 extend across the ECO cell 1200 in the x-axis direction (L to R or R to L). M0 track 1203 is actually cut by CMOB 265 (see FIGS. 12A, 12F) thereby converting M0 track 1203 into two electrically-isolated metal shapes 1203L and 1203R. V0 vias 1281, 1282A, 1282B, and 1283 couple the M0 layer to the M1 layer. The M1 layer includes M1 shapes 1271-1273 extending in the y-axis direction (B to T or T to B).

FIG. 12F illustrates the CPO layer and the CM0 layer. In particular, the CPO layer includes CPO shapes 1294 and 1296, which cut the polysilicon layer to make sure that there is not a polysilicon connection with vertically adjacent cells. The CPO layer also includes CPO shapes 1203′ and 1203″. CPO shape 1203′ cuts polysilicon shape 1210 at the mid-point of the ECO cell 1200, and no connection is made between VDD and VSS. CPO shape 1203″ cuts polysilicon shape 1213 on the right-most edge ensuring no unwanted connections. CM0 shapes 1261 and 1263 may cut the M0 metal layer on the left edge to prevent lateral connections. Similarly, CM0 shapes 1262 and 1264 may cut the M0 metal layer on the right edge to prevent lateral connections. The CM0 shapes 1261 and 1262 are CM0A mask shapes and CM0 shapes 1263 and 1264 CM0B shapes. These A and B designations are for separate cuts within a dual-mask process for the same layer to achieve the desired shape.

With that explanation of the specific shapes of the various layers, when they are put together into the ECO cell 1200 as illustrated in FIG. 12A, a generic ECO cell is provided.

VG vias 1226 and 1227 are in the same positions as the VG vias 1126 and 1127 of FIG. 11. Note that since there are no other VD customizations, the VG vias 1126 and 1127 have no specific function, but are left in place to show that the ECO cell 1200 may be created with minimal changes to the conventional logic cell 1100 to allow plug-and-play functionality.

With continued reference to FIG. 12A, one of the differences between the logic cell 1100 and the ECO cell 1200 is the placement of the VG vias associated with making connections to the M0 VSS and M0 VDD rails. Specifically, VG vias 1224 and 1225 are now located on the MD shapes 1230 and 1237, respectively. That is, instead of being placed interiorly of the first rail (the polysilicon shape 1110), but before the second rail (the polysilicon shape 1111), as illustrated in FIG. 11, the VG vias 1224 and 1225 are positioned outside the first rail (polysilicon shape 1210), closer to the edge L. Thus, the contacts are now on the cell left edge L. Thus, the VSS and VDD M0 rails now connect to the MD shapes 1230 and 1237, respectively. Ramifications of this placement will be further explored below.

With continued reference to FIG. 12A, the ECO cell 1200 has M0 tracks 1201 and 1205, which are dedicated to VSS and VDD, respectively in addition to the M0 VSS rail proximate the bottom of the ECO cell 1200 and the M0 VDD rail proximate the top of the ECO cell. 1200. Connections to the M0 tracks 1201 and 1205 are through fixed VD vias 1228 and 1229, respectively. Thus, the path formed from the VG contacts, the MP jumpers 1240 and 1247, and the vias 1228 and 1229 establish the M0 tracks 1201 and 1205 as the ECO cell 1200 VSS and VDD, respectively. When the ECO cell 1200 is customized, such customization may use these M0 tracks for VSS and VDD connections rather than have to couple to the M0 tracks 1206 and 1207 on the top and bottom of the ECO cell 1200. The source of NFET 1241 and the drain of PFET 1243 are connected to VSS and VDD, respectively through the vias 1228 and 1229. The drain of the NFET 1241, the source of the NFET 1242, and the drain of the NFET 1242 remain unconnected in the ECO cell 1200 allowing customization as explained in greater detail below. Likewise, the source of the PFET 1243, the drain of the PFET 1244, and the source of the PFET 1244 remain unconnected in the ECO cell 1200, again allowing customization as explained in greater detail below.

With continued reference to FIG. 12A, another difference between the logic cell 1100 and the ECO cell 1200 is the CMD shapes 1250 and 1251 along the top and bottom edges of the cell. The CMD shapes cut all MD shapes 1231-1236. Thus, no CMD modifications will be needed during an ECO. The CMD shape 1252 is identical to the CMD shape 1152 in FIG. 11.

The left and right edge base CM0A shapes 1261 and 1262 are identical to the CM0A shapes 1161 and 1162 of the logic cell 1100. However, the ECO cell 1200 has modified CM0B shapes 1263 and 1264 only cutting the M0 track 1203. Thus, the ECO cell M0 VSS 1201 and M0 VDD 1205 will be shared across all adjacent ECO cells creating a parallel VSS/VDD path throughout all ECO cells. CM0B 1265 is introduced to cut the M0 track 1203 at mid-track. This cut breaks the continuity between the device set of NFET 1241 and PFET 1243 and the device set of NFET 1242 and PFET 1244 through the VG vias 1226 and 1227, respectively. This CM0B 1265 allows the gates of these respective device sets to be connected as needed through other higher sequence masking steps.

The ECO cell 1200 incorporates fixed location M1 and V0 via shapes. A first M1 track 1271 is located to the left of the VG via 1226 in a first M1 track location. A V0 via 1281 is located at the intersection of the first M1 track 1271 and the M0 track 1203. This arrangement forms an M0 to M1 to VG connection. The gates of the first device set of the NFET 1241 and the PFET 1243 are now connected to the first M1 track 1271. Likewise a third M1 track 1273 is located to the right of the VG via 1227 in a third M1 track location. A V0 via 1283 is located at the intersection of the third M1 track 1273 and the M0 track 1203. This arrangement forms an M0 to M1 to VG connection. Thus, the gates of the second device set of the NFET 1242 and the PFET 1244 are now connected to the third M1 track 1273. Finally, a second M1 track 1272 is located between the first and the third M1 tracks 1271 and 1273. The second M1 track 1272 has two V0 vias associated with it. One V0 via 1282A intersects M0 track 1202 and another V0 via 1282B intersects M0 track 1204. Thus, the second M1 track 1272 connects the M0 tracks 1202 and 204.

The UHP ECO cell 1200 is different from the ECO cell 200 of FIG. 2A in that the UHP ECO cell 1200 includes the VG via 1225 on the M0 VDD rail and the VG via 1224 on the M0 VSS rail. Since the cell height is now taller, this architecture can support a direct connection of M0 track 1205 to VDD and M0 track 1201 to VSS. The MP jumpers 1240 and 1247 become redundant, but remain to provide a parallel path to the respective power supplies. Note further that while the use of the M0 and M1 layers in this fashion simplifies the design, other metal layers may be so used.

FIGS. 13-20 show possible customizations of the ECO cell 1200 of FIG. 12A to provide the same functions as those illustrated in FIGS. 3-10.

FIG. 13 illustrates the customization of the ECO cell 1200 of FIG. 12A to create a single-finger inverter function. In particular, the ECO cell 1200 has been modified to an inverter cell 1300 by placement of VD vias. That is, to create the single-finger inverter, the source and drain of a first NFET 1341 and a first PFET 1343 are connected to VSS and VDD, respectively while floating the gate input. These connections are accomplished by adding VD via 1391 at the intersection of M1 track 1372 and M0 track 1301 and VD via 1395 at the intersection of the M1 track 1372 and M0 track 1305. A second device set now has its PFET 1344 drain connected to VDD through the VD via 1395 and its NFET 1342 source connected to VSS through the VD via 1391. The source of the PFET 1344 is connected to M0 track 1304 through VD via 1394 and the drain of NFET 1342 is connected to M0 track 1302 through VD via 1392. Since the ECO cell 1200 already has V0 vias connecting the M1 track 1372 to the M0 tracks 1302 and 1304, this constitutes the output of the inverter. M0 track 1303 remains unchanged. Thus, the M1 track 1372 is the inverter output, and M1 track 1373 is the inverter input. M1 track 1371 floats. This customization is accomplished through the simple addition of the VD vias 1391, 1392, 1394, and 1395. In effect, a change to a single mask effectuates this change from the ECO cell 1200 to the inverter cell 1300.

FIG. 14 illustrates the customization of the ECO cell 1200 of FIG. 12A to create a two-finger inverter function. Compared to the ECO cell 1200, the only difference in inverter cell 1400 is the placement of the VD vias. To create a two-finger inverter, the source of a second NFET 1442 is connected to VSS by VD via 1491 and the drain of a second PFET 1444 is connected to VDD by VD via 1495. The sources of PFETs 1443 and 1444 are connected to M0 track 1404 through VD via 1494. The drain of NFETs 1441 and 1442 are connected to M0 track 1402 through VD via 1492. Since the ECO cell 1200 already has V0 vias connecting M1 track 1472 and M0 tracks 1402 and 1404, this arrangement constitutes the output of the inverter. M0 tracks 1401, 1403, and 1405 are unchanged. Thus, the M1 track 1472 is the inverter output and M1 track 1471 and M1 track 1473 are the inverter inputs. An M2 strap and associated V1 vias (not shown) will complete connection of the two M1 input tracks when this function is needed. Thus, the only changes to the ECO cell 1200 are the addition of the VD vias 1491, 1492, 1494, and 1495. To incorporate the inverter cell 1400, changes are made to the VD masks, the V1 masks, and the M2 masks.

FIG. 15 illustrates the customization of the ECO cell 1200 of FIG. 12A into a two-input NAND (NAND2) logic cell 1500. Again, the placement of the VD vias controls the customization and is the only change needed. The NAND2 function has A and B input PFETs 1543 and 1544 in parallel with the output and VDD while A and B input NFETs 1541 and 1542 are in series with one another between the output and VSS. Thus, to create the NAND2 logic cell 1500, the drain of the PFET 1544 is connected to VDD (M0 track 1505) using VD via 1595, and the sources of both the PFETs 1543 and 1544 are connected to M0 track 1504 by VD via 1594. The drain of the series connected NFET 1542 is connected to M0 track 1502 by VD via 1592. M0 tracks 1501 and 1503 are unchanged. Since the ECO cell 1200 already has V0 vias connecting M1 track 1572 to M0 tracks 1502 and 1504, the output of the NAND2 logic cell 1500 is available. That is, the M1 track 1572 is the NAND2 logic cell 1500 output, and M1 track 1571 and M1 track 1573 are the NAND2 A and B inputs. Again, the only change is the addition of the VD vias 1592, 1594, and 1595, requiring only a change in the VD mask.

FIG. 16 illustrates the customization of the ECO cell 1200 of FIG. 12A into a two-input NOR (NOR2) logic cell 1600. Again, the placement of the VD vias controls the customization and is the only change needed. The NOR2 function has A and B input PFETs 1643 and 1644 in series with one another between VDD and output M0 track 1604. A and B input NFETs 1641 and 1642 are in parallel with one another with their respective sources connected to VSS and shared drains connected to output M0 track 1602. Thus, to create the NOR2 logic cell 1600, the drain of the PFET 1644 is connected to the output M0 track 1604 using VD via 1694, and the sources of both the NFETs 1641 and 1642 are connected to the output M0 track 1602 using VD via 1692. The source of the parallel connected NFET 1642 is connected to VSS M0 track 1601 with VD via 1691. Since the ECO cell 1200 already has V0 vias connecting M1 track 1672 to M0 tracks 1602 and 1604, the output is present. That is, the M1 track 1672 is the NOR2 logic cell 1600 output, and M1 track 1671 and M1 track 1673 are the NOR2 logic cell 1600 A and B inputs. M0 tracks 1603 and 1605 are unchanged. Again, the only changes to the ECO cell 1200 are the inclusion of the VD vias 1691, 1692, and 1694.

FIG. 17 illustrates the customization of the ECO cell 1200 of FIG. 12A to create a single-finger stacked inverter cell 1700. In particular, the stacked inverter cell 1700 is farmed from a series stack of two PFETs 1743 and 1744 connected between VDD and the output and a series stack of two NFETs 1741 and 1742 connected between the output and VSS. The gates of all the devices are common. The ECO cell 1200 is modified by the addition of VD vias. In particular, the drain of a second NFET 1742 is connected to M0 output track 1702 by means of VD via 1792, and the drain of a second PFET 1744 is connected to M0 track 1704 by VD via 1794. Since the V0 vias of the ECO cell 1200 already connect M1 track 1772 to the M0 tracks 1702 and 1704, the output is already formed. That is, the M1 track 1772 is the stacked inverter output and M1 track 1771 and M1 track 1773 are the gate inputs. The gate inputs will be connected together using a higher-level metal and an associated V1 via. Thus, changes to the VD masks and the higher-level metal masks are required but are still not considered too disruptive to the entire mask stack. The change to the ECO cell 1200 is the addition of the VD vias 1792 and 1794. M0 tracks 1701, 1703, and 1705 are unchanged.

FIG. 18A illustrates a tie-high circuit 1800 using two ECO cells 1200 while FIG. 18B provides a schematic view of the tie-high circuit 1800. In particular, the tie-high circuit 1800 includes a first ECO cell 18010, which has NFETs 1841 and 1842 as well as PFETs 1843 and 1844. A second ECO cell 18020 has NFETs 1845 and 1846 and PFETs 1847 and 1848. The M1 tracks in the first ECO cell 18010 are labeled as 1871-1873 while those in the second ECO cell 18020 are labeled as 1875-1877. M0 tracks 1801 and 1805 are continuous across both the ECO cells 18010 and 18020. M0 tracks 1802, 1803, and 1804 within the first ECO cell 18010 are isolated from M0 tracks 1812, 1813, and 1814 in the second ECO cell 18020 by the cutouts CM0A 1261 and 1262 and CM0B 1263 and 1264 described in FIG. 12F.

With continued reference to FIGS. 18A and 18B, a supplemental NFET device (suppl_n) is a pair of NFETs 1841 and 1842, and a supplemental PFET device (suppl_p) is a pair of PFETs 1847 and 1848. The sources and drains of the NFETs 1841 and 1842 are connected to VSS through VD vias 1891A and 1891B. The sources and drains of the PFETs 1847 and 1848 are connected to VDD through VD vias 1895B and 1895C. The PFETs 1843 and 1844 are the associated with a transistor MPA of FIG. 18B, and the NFETs 1845 and 1846 are associated with a transistor MNA of FIG. 18B. All the transistors shown in FIG. 18B have common gate connections. These connections are made by the addition of M2 shape 1880 and V1 vias 1881, 1883, 1885, 1886, and 1887. V1 via 1886 connects the outputs of the MNA NFETs 1845 and 1846 to all the device gates in the ECO cells 18010 and 18020. VD via 18912 connects the drains of the parallel NFETs 1845 and 1846 to the M0 track 1812 through the V1 via 1886 to the M2 shape 1880. The source of the NFET 1846 is connected to VSS through VD via 1891C. The drain of the PFET 1844 is connected to VDD through VD via 1895A. The source of the PFET pair 1843 and 1844 (MPA in FIG. 18B) is connected to the M0 track 1804 through VD via 18904 and is the output of the tie-high circuit 1800. That is, M1 track 1872 is the tie-up output (logic _1_pin in FIG. 18B). M1 tracks 1871, 1873, 1875, 1876, and 1877 are all connected together by the M2 shape 1880.

Thus, the tie-high circuit 1800 is accomplished by a pair of ECO cells 1200 with the addition of the VD vias 1891A, 1891B, 1891C, 1895A, 1895B, 1895C, 18904, and 18912, and the V1 vias 1881, 1883, 1885, 1886, and 1887 as well as the M2 shape 1880. While this requires changes on three mask layers, the more complex functionality of the tie-high circuit 1800 is still effectuated with minimal changes to the mask stack. Further, these changes still occur relatively deep in the MEOL stack.

Similarly, FIGS. 19A and 19B illustrate a tie-low circuit 1900 formed from two ECO cells 1200. The tie-low circuit 1900 generally requires only PFET MPA and NFET MNA. The supplemental elements are available with the ECO cells 1200. In particular, FIG. 19A illustrates ECO cell 19010 with NFETs 1941 and 1942 and PFETs 1943 and 1944 as well as M1 tracks 1971-1973. ECO cell 19020 includes NFETs 1945 and 1946 and PFETs 1947 and 1948 as well as M1 tracks 1975-1977. M0 tracks 1901 and 1905 are continuous across both the ECO cells 19010 and 19020. M0 tracks 1902, 1903, and 1904 are isolated from M0 tracks 1912, 1913, and 1914 by the cutouts CM0A 1261 and 1262 and CM0B 1263 and 1264 described in FIG. 12F.

With continued reference to FIGS. 19A and 19B, the supplemental NFET device (suppl_n) is a pair of NFETs 1945 and 1946, and the supplemental PFET device (suppl_p) is a pair of PFETs 1943 and 1944. The sources and drains of the NFETs 1945 and 1946 are connected to VSS through VD vias 1991B and 1991C. The sources and drains of the PFETs 1943 and 1944 are connected to VDD through VD vias 1995A and 1995B. The PFETs 1947 and 1948 are the associated with transistor MPA of FIG. 19B, and the NFETs 1941 and 1942 are associated with transistor MNA of FIG. 19B. PFET 1948 is coupled to VDD through VD via 1995C. All the transistors shown in FIG. 19B have common gate connections. These connections are made by the addition of M2 shape 1980 and V1 vias 1981, 1983, 1985, 1986, and 1987. V1 via 1986 connects the outputs of the MPA PFETs 1947 and 1948 to all the device gates in the ECO cells 19010 and 19020. VD via 19914 connects the drain of the parallel PFETs 1947 and 1948 to the M0 track 1914 through the V1 via 1986 to the M2 shape 1980. The source of the NFET 1942 is connected to VSS through VD via 1991A. The drains of NFETs 1941 and 1942 are connected to the output through added VD via 1992. The source of the PFET pair 1947 and 1948 (MPA in FIG. 1913) is connected to the M0 track 1914 through VD via 19914. That is, M1 track 1972 is the tie-low output (logic in FIG. 19B). M1 tracks 1971, 1973, 1975, 1976, and 1977 are all connected together by the M2 shape 1980.

Thus, the tie-low circuit 1900 is accomplished by a pair of ECO cells 1200 with the addition of the VD vias 1991A, 1991B, 1991C, 1995A, 1995B, and 1995C, and the V1 vias 1981, 1983, 1985, 1986, and 1987 as well as the M2 shape 1980. While this requires changes on three mask layers, the more complex functionality of the tie-low circuit 1900 is still effectuated with minimal changes to the mask stack. Further, these changes still occur relatively deep in the MEOL stack.

Another possible function is a DCAP. DCAPs are often used in filler space. Since the interconnections and/or arrangement of mask shapes are optimized for the standard cell like other logic functions, it is not always easy to convert a DCAP to another function without extensive mask changes. However, exemplary aspects of the present disclosure allow ready conversion from the ECO cell 1200 to a DCAP as well as the ability to change the DCAP to the ECO cell 1200 without extensive mask work.

FIGS. 20A and 20B illustrate a two-cell DCAP circuit 2000 with accompanying schematic diagram in FIG. 20B. FIG. 20B illustrates the DCAP circuit 2000 in a configuration such that no FET gate is tied directly to VDD or VSS. Further, the DCAP circuit 2000 only requires PFET and NFET devices labeled as MPA, MPBIAS, MNA, and MNBIAS. Supplemental devices are included to afford the layout using the ECO cells 1200.

With the knowledge of how the DCAP circuit 2000 is laid out, it is readily able to be translated into using the ECO cells 1200. In particular, two ECO cells 20010 and 20020 are used. The ECO cell 20010 has NFETs 2041 and 2042 and PFETs 2043 and 2044. Similarly, the ECO cell 20020 has NFETs 2045 and 2046 and PFETs 2047 and 2048. M1 tracks 2071-2073 are used in ECO cell 20010. M1 tracks 2075-2077 are used in the ECO cell 20020. M0 tracks 2001 and 2005 are continuous across both the ECO cells 20010 and 20020 to provide a continuous VSS and VDD, respectively. M0 tracks 2002, 2003, and 2004 are isolated from M0 tracks 2012, 2013, and 2014 by cutouts CM0A 1261 and 1262 and CM0B 1263 and 1264 as previously explained. Mapping FIG. 20A to the elements in FIG. 20B shows that the NFET 2041 is MNA; the NFET 2042 is MNBIAS; the NFET 2045 is Suppl_n_pbias; the NFET 2046 is Suppl_n_nbias; the PFET 2043 is Suppl_p_nbias, the PFET 2044 is Suppl_p_pbias; the PFET 2047 is MPBIAS; and the PFET 2048 is MPA.

With continued reference to FIGS. 20A and 20B, the ECO cells 1200 are further modified by the addition of M2 shape 2079, which provides interconnections through added V1 vias 2083, 2085, and 2086 to the M1 tracks 2073, 2075, and 2076, respectively. This arrangement forms the pbias metal network. Likewise, the ECO cells 1200 are further modified by the addition of M2 shape 2080, which provides interconnections through added V1 vias 2081, 2082, and 2087 to the M1 tracks 2071, 2072, and 2077, respectively. This arrangement forms the nbias metal network. To complete all the source and drain connections, VD vias 2091A, 2091B, 2091C, 2092, 2095A, 2095B, 2095C, and 201014 are also added.

It should be appreciated that much like the vertical DCAP described above for the ECO cell 200, the same vertical arrangement may be made for the ECO cell 1200.

FIG. 21 provides a simplified flowchart of a process 2100 of using the ECO cells 200 and 1200 of FIGS. 2A and 12A in silicon manufacturing. The process 2100 begins by designing a circuit (block 2102) including placing the ECO cells 200, 1200 as filler cells in the design (block 2104). Masks are made based on the design (block 2106), and silicon is manufactured using the masks (block 2018). At some point, a design error is identified (block 2110). Based on the detected error. ECO cells within the original design are identified as candidates for modification to fix the error (block 2112) (e.g., replace a defective NAND gate with an ECO cell modified to be a NAND gate). The identified ECO cell 200, 1200 is modified to provide the desired functionality (block 2114) and the relevant masks are modified (block 2116). As noted above, the masks needing modification are typically only the VD masks and are late in the MEOL process stack, with few if any changes needed in subsequent stacks (e.g., the V1 and M2 masks may also need modification). Silicon is manufactured based on the modified mask stack (block 2118).

The ECO cell architecture and implementation according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multi copter.

In this regard, FIG. 22 illustrates an example of a processor-based system 2200 that can employ the ECO cell 200 or the UHP ECO cell 1200 illustrated in FIGS. 2A and 12A or customized versions such as those cells illustrated in FIG. 3-10 or 13-20. In this example, the processor-based system 2200 includes one or more central processing units (CPUs) 2202, each including one or more processors 2204. The CPU(s) 2202 may have cache memory 2206 coupled to the processor(s) 2204 for rapid access to temporarily stored data. The CPU(s) 2202 is coupled to a system bus 2208 and can intercouple master and slave devices included in the processor-based system 2200. As is well known, the CPU(s) 2202 communicates with these other devices by exchanging address, control, and data information over the system bus 2208. For example, the CPU(s) 2202 can communicate bus transaction requests to a memory controller 2210 as an example of a slave device. Although not illustrated in FIG. 22, multiple system buses 2208 could be provided, wherein each system bus 2208 constitutes a different fabric.

Other master and slave devices can be connected to the system bus 2208. As illustrated in FIG. 22, these devices can include a memory system 2212, one or more input devices 2214, one or more output devices 2216, one or more network interface devices 2218, and one or more display controllers 2220 as examples. The input device(s) 2214 can include any type of input device, including, but not limited to, input keys, switches, voice processors, etc. The output device(s) 2216 can include any type of output device, including, but not limited to, audio, video, other visual indicators, etc. The network interface device(s) 2218 can be any devices configured to allow exchange of data to and from a network 2222. The network 2222 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 2218 can be configured to support any type of communications protocol desired. The memory system 2212 can include one or more memory units 2224 (0-N).

The CPU(s) 2202 may also be configured to access the display controller(s) 2220 over the system bus 2208 to control information sent to one or more displays 2226. The display controller(s) 2220 sends information to the display(s) 2226 to be displayed via one or more video processors 2228, which process the information to be displayed into a format suitable for the display(s) 2226. The display(s) 2226 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof,

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

1. What is claimed is:
An engineering change order (ECO) cell comprising:
a rectilinear outline comprising four edges; and
a circuit comprising:
a first metal layer (M0) comprising a first portion and a second portion, the first portion positioned generally adjacent a first edge of the four edges and configured to be coupled to a power source and the second portion positioned generally adjacent a second edge of the four edges and configured to be coupled to a ground, wherein the first edge and the second edge are opposite one another on the rectilinear outline, the first metal layer further comprising a first M0 track, a second M0 track, a third M0 track, a fourth M0 track, and a fifth M0 track;
a second metal layer (M1) comprising a first M1 track, a second M1 track, and a third M1 track;
a first path coupling the first portion of the first metal layer to the first M0 track through a first VG via, a first jumper, and a first VD via, wherein the first VG via is positioned proximate an intersection of the first edge and a third edge and the first VD via;
a second path coupling the second portion of the first metal layer to the fifth M0 track through a second VG via, a second jumper, and a second VD via, wherein the second VG via is positioned proximate an intersection of the second edge and the third edge;
a first V0 via coupling the first M1 track to the third M0 track;
a second V0 via coupling the third M1 track to the third M0 track;
a third V0 via coupling the second M1 track to the second M0 track; and
a fourth V0 via coupling the second M1 track to the fourth M0 track.

2. The ECO cell of claim 1, wherein the circuit forms an inverter.

3. The ECO cell of claim 2, wherein the inverter comprises a single-finger inverter.

4. The ECO cell of claim 3, further comprising a third VD via coupling the second M1 track to the fifth M0 track and a fourth VD via coupling the second M1 track to the first M0 track.

5. The ECO cell of claim 1, further comprising a first diffusion region and a second diffusion region positioned below the first metal layer.

6. The ECO cell of claim 5, further comprising four polysilicon shapes positioned above the first and second diffusion regions and below the first metal layer.

7. The ECO cell of claim 6, further comprising a cut region that separates a first polysilicon shape of the four polysilicon shapes into a first top half and a first bottom half, and wherein the cut region further separates a second polysilicon shape of the four polysilicon shapes into a second top half and a second bottom half.

8. The ECO cell of claim 7, wherein the first diffusion region, the first top half, and the second top half form two p-type Field-Effect Transistors (FETs) (PFETs) and the second diffusion region and the two polysilicon shapes form two n-type FETs (NFETs).

9. The ECO cell of claim 8, wherein the circuit forms a two-finger inverter.

10. The ECO cell of claim 9, wherein the two-finger inverter comprises a third VD via coupling a second NFET of the two NFETs to the fifth M0 track and a fourth VD via coupling a second PFET of the two PFETs to the first M0 track.

11. The ECO of claim 10, wherein the third VD via couples to a source of the second NFET and the fourth VD via couples to a drain of the second PFET.

12. The ECO cell of claim 8, wherein the circuit forms a NAND gate.

13. The ECO cell of claim 12, wherein the NAND gate comprises:
a third VD via coupling a second PFET of the two PFETs to the first M0 track;
a fourth VD via coupling both of the two PFETs to the second M1 track; and
a fifth VD via coupling a second NFET of the two NFETs to a fourth M1 track.

14. The ECO cell of claim 13, wherein the third VD via couples to a drain of the second PFET, the fourth VD via couples to sources of both of the two PFETs, and the fifth VD via couples to a drain of the second NFET.

15. The ECO cell of claim 8 wherein the circuit forms a NOR gate.

16. The ECO cell of claim 15, wherein the NOR gate comprises:
a third VD via coupling a second PFET of the two PFETs to the second M1 track;
a fourth VD via coupling both of the two NFETs to a fourth M1 track; and
a fifth VD via coupling a second NFET of the two NFETs to a fifth M1 track.

17. The ECO cell of claim 16, wherein the third VD via couples to a drain of the second PFET, the fourth VD via couples to sources of both of the two NFETs, and the fifth VD via couples to a drain of the second NFET.

18. The ECO cell of claim 1 integrated into an integrated circuit (IC).

19. The ECO cell of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

20. A decoupling capacitor (DCAP) cell comprising:
a first generic cell comprising a first circuit comprising:
a first metal layer (M0) comprising a first portion and a second portion, the first portion positioned generally adjacent a first edge of four edges and configured to be coupled to a power source and the second portion positioned generally adjacent a second edge of the four edges and configured to be coupled to a ground, wherein the first edge and the second edge are opposite one another on a rectilinear outline, the first metal layer further comprising a first M0 track, a second M0 track, a third M0 track, a fourth M0 track, and a fifth M0 track;
a second metal layer (M1) comprising a first M1 track, a second M1 track, and a third M1 track;
a first path coupling the first portion of the first metal layer to the first M0 track through a first VG via, a first jumper, and a first VD via, wherein the first VG via is positioned proximate an intersection of the first edge and a third edge and the first VD via;
a second path coupling the second portion of the first metal layer to the fifth M0 track through a second VG via, a second jumper, and a second VD via, wherein the second VG via is positioned proximate an intersection of the second edge and the third edge;
a first V0 via coupling the first M1 track to the third M0 track;
a second V0 via coupling the third M1 track to the third M0 track;
a third V0 via coupling the second M1 track to the second M0 track; and
a fourth V0 via coupling the second M1 track to the fourth M0 track; and
a second generic cell adjacent to the first generic cell, the second generic cell comprising a second circuit.

21. The DCAP cell of claim 20, wherein the first generic cell is horizontally adjacent the second generic cell.

22. The DCAP cell of claim 21, wherein the first M0 track and the fifth M0 track are continuous across both the first and second generic cells.

23. The DCAP cell of claim 21, wherein the second M0 track, the third M0 track, and the fourth M0 track are isolated from the second generic cell.

24. The DCAP cell of claim 21, further comprising an third metal layer (M2) shape providing interconnections between the third M1 track and an M1 track in the second generic cell.

25. The DCAP cell of claim 24, wherein the third M1 track couples to the M2 shape through a V1 via.

26. The DCAP of claim 20, wherein the first generic cells vertically adjacent the second generic cell.

27. A tie-high circuit comprising;
a first generic cell comprising a first circuit, the first circuit comprising:
a first metal layer (M0) comprising a first portion and a second portion, the first portion positioned generally adjacent a first edge of four edges and configured to be coupled to a power source and the second portion positioned generally adjacent a second edge of the four edges and configured to be coupled to a ground, wherein the first edge and the second edge are opposite one another on a rectilinear outline, the first metal layer further comprising a first M0 track, a second M0 track, a third M0 track, a fourth M0 track, and a fifth M0 track;
a second metal layer (M1) comprising a first M1 track, a second M1 track, and a third M1 track;
a first path coupling the first portion of the first metal layer to the first M0 track through a first VG via, a first jumper, and a first VD via, wherein the first VG via is positioned proximate an intersection of the first edge and a third edge and the first VD via;
a second path coupling the second portion of the first metal layer to the fifth M0 track through a second VG via, a second jumper, and a second VD via, wherein the second VG via is positioned proximate an intersection of the second edge and the third edge;
a first V0 via coupling the first M1 track to the third M0 track;
a second V0 via coupling the third M1 track to the third M0 track;
a third V0 via coupling the second M1 track to the second M0 track; and
a fourth V0 via coupling the second M1 track to the fourth M0 track; and
a second generic cell adjacent to the first generic cell, the second generic cell comprising a second circuit;
wherein the first and fifth M0 tracks are continuous across the first generic cell and the second generic cell.

28. A tie-low circuit comprising;
a first generic cell comprising a first circuit, the first circuit comprising:
a first metal layer (M0) comprising a first portion and a second portion, the first portion positioned generally adjacent a first edge of four edges and configured to be coupled to a power source and the second portion positioned generally adjacent a second edge of the four edges and configured to be coupled to a ground, wherein the first edge and the second edge are opposite one another on a rectilinear outline, the first metal layer further comprising a first M0 track, a second M0 track, a third M0 track, a fourth M0 track, and a fifth M0 track;
a second metal layer (M1) comprising a first M1 track, a second M1 track, and a third M1 track;
a first path coupling the first portion of the first metal layer to the first M0 track through a first VG via, a first jumper, and a first VD via, wherein the first VG via is positioned proximate an intersection of the first edge and a third edge and the first VD via;
a second path coupling the second portion of the first metal layer to the fifth M0 track through a second VG via, a second jumper, and a second VD via, wherein the second VG via is positioned proximate an intersection of the second edge and the third edge;
a first V0 via coupling the first M1 track to the third M0 track;
a second V0 via coupling the third M1 track to the third M0 track;
a third V0 via coupling the second M1 track to the second M0 track; and
a fourth V0 via coupling the second M1 track to the fourth M0 track; and
a second generic cell adjacent to the first generic cell, the second generic cell comprising a second circuit;
wherein the first and fifth M0 tracks are continuous across the first generic cell and the second generic cell.

29. A method of manufacturing an integrated circuit (IC), comprising:
designing a circuit with one or more engineering change order (ECO) cells as filler cells;
making a mask stack to be used in the manufacture of the IC;
identifying a design error in the IC;
identifying at least one of the one or more ECO cells that may be modified to address the design error;
modifying a design of the IC to modify the at least one of the one or more ECO cells;
modifying the mask stack deep in a middle-end-of-line (MEOL) process; and
making the IC based on the modified mask stack.
